(19) United States
(12) Patent Application Publication
(10) Pub. No.: US 2024/0074237 A1
(43) Pub. Date: Feb. 29, 2024

(54) DISPLAY PANEL AND DISPLAY DEVICE

(71) Applicant: Xiamen Tianma Display Technology Co., Ltd., Xiamen (CN)

(72) Inventors: Xuanyun Wang, Xiamen (CN); Jianlong Wu, Xiamen (CN)

(73) Assignee: Xiamen Tianma Display Technology Co., Ltd., Xiamen (CN)

(21) Appl. No.: 18/387,277

(22) Filed: Nov. 6, 2023

(30) Foreign Application Priority Data
Mar. 15, 2023 (CN) 202310247882.0

(51) Int. Cl. H10K 59/121; G09G 3/20; G09G 3/3233; H10K 59/131; H10K 59/35

(52) U.S. Cl. CPC H10K 59/1213; G09G 3/2074; G09G 3/3233; H10K 59/131; H10K 59/352; G09G 2300/0426; G09G 2300/0819; G09G 2300/0842; G09G 2320/0257; G09G 2320/0666

(57) ABSTRACT

A display panel includes multiple pixel cells, each pixel cell includes at least two sub-pixels, each sub-pixel includes a pixel circuit and a light-emitting element, and the pixel circuit includes a drive transistor. The at least two sub-pixels include a first sub-pixel and a second sub-pixel. The drive transistor of the pixel circuit in the first sub-pixel includes a first channel, and the drive transistor of the pixel circuit in the second sub-pixel includes a second channel. The first sub-pixel in the display panel is configured to emit green light, and the second sub-pixel in the display panel is configured to emit red light and/or blue light, and a width-to-length ratio of a first channel of a drive transistor in the first sub-pixel is greater than a width-to-length ratio of a second channel of a drive transistor in the second sub-pixel.

### CROSS-REFERENCE TO RELATED APPLICATION

This application claims priority to Chinese Patent Application No. 202310247882.0 filed Mar. 15, 2023, the disclosure of which is incorporated herein by reference in its entirety.

### TECHNICAL FIELD

The present disclosure relates to the field of display technologies, and in particular to, a display panel and a display device.

### BACKGROUND

An organic light-emitting diode (OLED) display panel has the advantages of high visibility, high brightness, and being lighter and thinner, and thus, the application of the OLED display panel is becoming increasingly wider.

However, when the OLED display panel presents a low gray scale image or a changed image, for example, when the OLED display panel is switched from a black picture to a white picture, display defects such as the occurrence of the dragging shadow may be observed on the display panel.

### SUMMARY

The present disclosure provides a display panel and a display device, to improve the display defect such as a dragging shadow.

According to an aspect of the present disclosure, there is provided a display panel. The display panel includes multiple pixel cells, each of the multiple pixel cells includes at least two sub-pixels, each of the at least two sub-pixels includes a pixel circuit and a light-emitting element, the pixel circuit is configured to drive the light-emitting element to emit light, the pixel circuit includes a drive transistor. The at least two sub-pixels include a first sub-pixel and a second sub-pixel, the first sub-pixel is configured to emit green light, and the second sub-pixel is configured to emit red light and/or blue light. The drive transistor of the pixel circuit in the first sub-pixel includes a first channel, and the drive transistor of the pixel circuit in the second sub-pixel includes a second channel. A width-to-length ratio of the first channel is greater than a width-to-length ratio of the second channel.

According to another aspect of the present disclosure, there is provided a display device including the display panel described above.

It should be understood that the contents described in this section are not intended to identify the embodiments of the present disclosure, nor intended to limit the scope of the present disclosure. Other features of the present disclosure will be readily understood from the following description.

### BRIEF DESCRIPTION OF DRAWINGS

In order to more clearly explain the schemes in embodiments of the present disclosure, the drawings used for describing the embodiments will be briefly introduced below. The drawings in the following description are merely some embodiments of the present disclosure. For those of ordinary skill in the art, other drawings may also be obtained without creative labor according to these drawings.

FIG. 1 is a schematic structural view of a display panel according to an embodiment of the present disclosure;

FIG. 2 is a schematic structural cross-sectional view of FIG. 1 taken along a direction of A-A′;

FIG. 3 is a schematic structural view of a pixel circuit according to an embodiment of the present disclosure;

FIG. 4 is a schematic view of a dragging shadow phenomenon of a display panel according to an embodiment of the present disclosure;

FIG. 5 is schematic view showing a color scale of part of pixel cells of FIG. 4;

FIG. 6 is a schematic structural view of a pixel circuit according to an embodiment of the present disclosure;

FIG. 7 is a schematic view showing a partial structure of the pixel circuit of FIG. 6;

FIG. 8 is a schematic view showing a partial structure of a pixel circuit according to an embodiment of the present disclosure;

FIG. 9 is a schematic view showing a partial structure of another pixel circuit according to an embodiment of the present disclosure;

FIG. 10 is a schematic structural view of a first channel and a second channel according to an embodiment of the present disclosure;

FIG. 11 is a schematic structural view of another first channel and another second channel according to an embodiment of the present disclosure;

FIG. 12 is a schematic view showing a partial structure of still another pixel circuit according to an embodiment of the present disclosure;

FIG. 13 is a schematic structural view of still another first channel and still another second channel according to an embodiment of the present disclosure;

FIG. 14 is a schematic structural view of another display panel according to an embodiment of the present disclosure;

FIG. 15 is schematic structural cross-sectional view of FIG. 14 taken along a direction of B-B′;

FIG. 16 is a schematic view showing a partial cross-sectional structure of a display panel according to an embodiment of the present disclosure;

FIG. 17 is a schematic view showing a partial cross-sectional structure of another display panel according to an embodiment of the present disclosure;

FIG. 18 is a schematic view showing a partial cross-sectional structure of still another display panel according to an embodiment of the present disclosure;

FIG. 19 is a schematic structural view of another pixel circuit according to an embodiment of the present disclosure;

FIG. 20 is a schematic view showing a partial structure of the pixel circuit of FIG. 19;

FIG. 21 is a schematic structural view of still another display panel according to an embodiment of the present disclosure;

FIG. 22 is schematic structural cross-sectional view of FIG. 21 taken along a direction of C-C′;

FIG. 23 is a schematic view showing a partial cross-sectional structure of still another display panel according to an embodiment of the present disclosure;

FIG. 24 is a schematic view showing a partial cross-sectional structure of still another display panel according to an embodiment of the present disclosure; and

FIG. 25 is a schematic structural view of a display device according to an embodiment of the present disclosure.

### DETAILED DESCRIPTION

In order that schemes of the present disclosure may be better understood by those skilled in the art, schemes in the embodiments of the present disclosure will be clearly and completely described below in conjunction with the drawings in the embodiments of the present disclosure. The described embodiments are part of the embodiments of the present disclosure, rather than all of the embodiments of the present disclosure. All other embodiments obtained by those of ordinary skill in the art based on the embodiments of the present disclosure without requiring creative efforts shall all fall within the scope of protection of the present disclosure.

It should be noted that the terms “first,” “second,” and the like in the Description and claims of the present disclosure, and in the foregoing drawings, are used for distinguishing between similar objects and not necessarily for describing a particular order or sequential order. It should be understood that the data so used may be interchanged as appropriate so that the embodiments of the present disclosure described herein may be implemented in an order other than those illustrated or described herein. Furthermore, the terms “including” and “having”, as well as any variations thereof, are intended to cover a non-exclusive inclusion, for example, a process, a method, a system, a product, or an apparatus that includes a series of steps or units is not necessarily limited to those steps or units expressly listed, but may include other steps or units not expressly listed or inherent to such process, method, product, or apparatus.

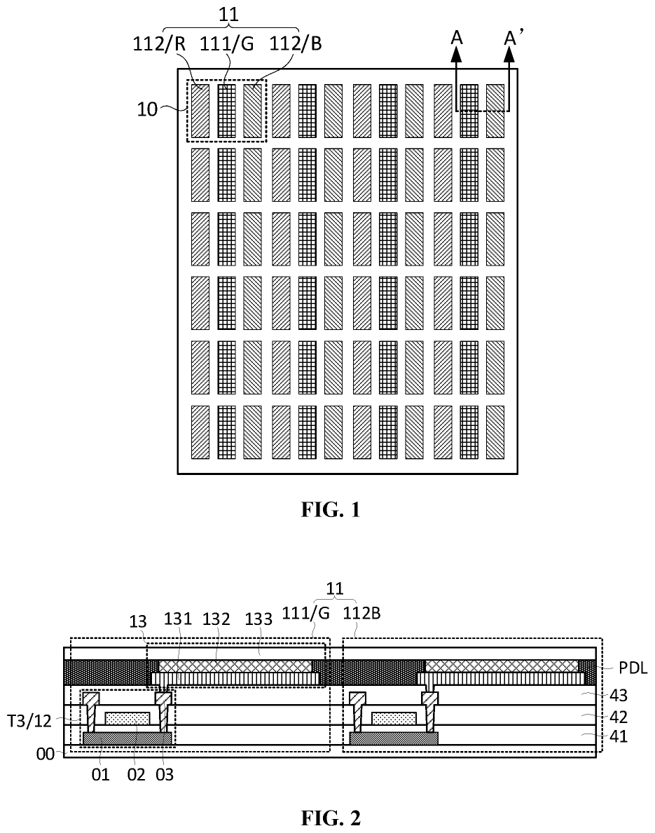

FIG. 1 is a schematic structural view of a display panel according to an embodiment of the present disclosure, and FIG. 2 is a schematic structural cross-sectional view of FIG. 1 taken along a direction of A-A′. As shown in FIGS. 1 and 2, the display panel according to the embodiment of the present disclosure includes multiple pixel cells 10, each of the multiple pixel cells 10 includes at least two sub-pixels 11, each of the at least two sub-pixels 11 includes a pixel circuit 12 and a light-emitting element 13, the pixel circuit 12 is configured to drive the light-emitting element 13 to emit light, and the pixel circuit 12 includes a drive transistor T3. The at least two sub-pixels 11 include a first sub-pixel 111 and a second sub-pixel 112, the first sub-pixel 111 is configured to emit green light, and the second sub-pixel 112 is configured to emit red light and/or blue light. The drive transistor T3 of the pixel circuit 12 in the first sub-pixel 111 includes a first channel 21, the drive transistor T3 of the pixel circuit 12 in the second sub-pixel 112 includes a second channel 22, and a width-to-length ratio of the first channel 21 is greater than a width-to-length ratio of the second channel 22.

Specifically, the display panel provided in this embodiment may be an organic light-emitting diode (OLED) display panel, the display panel is provided with the multiple pixel cells 10 arranged in array, the pixel cell 10 may include at least two sub-pixels 11 of different colors, for example, as shown in FIG. 1, the pixel cell 10 may include a red sub-pixel R, a green sub-pixel G and a blue sub-pixel B, and in other embodiments, the pixel cell 10 may also include a white sub-pixel and the like to achieve the color image display. Here, the sub-pixels 11 may be arranged in array on the display panel, or may be arranged in other arrangement manners. FIG. 1 is exemplified by only using an example in which the multiple sub-pixels 11 are arranged in array, it is to be understood that FIG. 1 is exemplified by using an example in which a shape of a light-emitting region of the sub-pixel 11 is rectangular. In other embodiments, the shape of the light-emitting region of the sub-pixel 11 includes, but not limited to, this shape, and may be designed according to actual requirements.

Further, the sub-pixel 11 includes the pixel circuit 12 and the light-emitting element 13. As shown in FIG. 2, the light-emitting element 13 may be an organic light-emitting diode, but not limited thereto. As shown in FIG. 2, an example in which the light-emitting element 13 is the organic light-emitting diode is described. The organic light-emitting diode may include an anode layer 131, a light-emitting layer 132 and a cathode layer 133 disposed in a stacked manner. When electrons and holes are injected into the light-emitting layer 132 from the cathode layer 133 and the anode layer 131, respectively, excitons are formed in the light-emitting layer 132 and light-emitting molecules are excited so that the light-emitting layer 132 emits visible light. Here, it is possible to emit visible light of different colors by setting the material of the light-emitting layer 132 to be different.

For example, in this embodiment, the pixel cell 10 may be set to include at least the first sub-pixel 111 and the second sub-pixel 112. The light-emitting layer 132 of the light-emitting element 13 in the first sub-pixel 111 is an organic light-emitting material that emits the green light, and the light-emitting layer 132 of the light-emitting element 13 in the second sub-pixel 112 is an organic light-emitting material that emits the red light and/or the blue light, so that the first sub-pixel 111 emits the green light and the second sub-pixel 112 emits the red light and/or the blue light.

Further, the pixel circuit 12 is electrically connected to the light-emitting element 13, and the pixel circuit 12 is configured to transmit a light-emitting drive current to the light-emitting element 13 under the action of a signal of a drive signal line (such as, a scan line, a data line, a voltage signal line) on the display panel, thereby supplying the drive current to the light-emitting element 13 to drive the light-emitting element 13 to emit light.

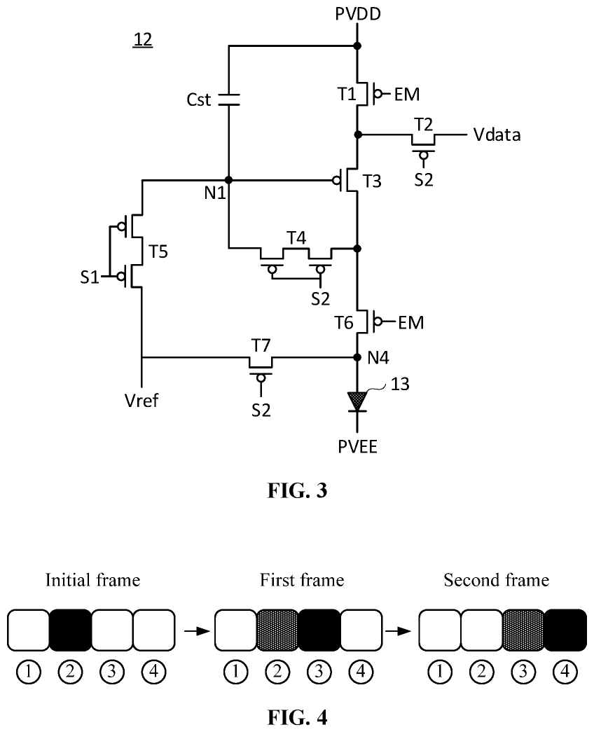

FIG. 3 is a schematic structural view of a pixel circuit according to an embodiment of the present disclosure. Exemplarily, as shown in FIGS. 2 and 3, the pixel circuit 12 includes the drive transistor T3, the drive transistor T3 may include an active layer 01, a gate layer 02 and a source and drain electrode layer 03 disposed on a base substrate 00 in a stacked manner, the drive transistor T3 and the light-emitting element 13 are connected in series between a first power supply signal line PVDD and a second power supply signal line PVEE, and a voltage on the first power supply signal line PVDD is greater than a voltage on the second power supply signal line PVEE.

Here, the drive transistor T3 may be turned on according to a potential of a gate of the drive transistor T3, and drive current formed by the turn-on of the drive transistor T3 is used for driving the light-emitting element 13 to emit light. It is to be understood that the drive transistor T3 is used as a drive tube, the potential of the gate of the drive transistor T3 determines the magnitude of the drive current formed by the turn-on of the drive transistor T3, whereby the light-emitting brightness of the light-emitting element 13 may be adjusted by controlling a gate voltage of the drive transistor T3, thereby controlling the gray scale.

A drive current I generated by the drive transistor T3 may satisfy the following formula:

I=(½)Cₒₓμ(W/L)(Vgs−Vth)²

Where μ is a carrier mobility of the drive transistor T3, W/L is a width-to-length ratio of a channel of the drive transistor T3, Cₒₓ is a gate oxide layer capacitance per unit area of the drive transistor T3, Vgs is a voltage difference between a gate and a source of the drive transistor T3, and Vth is a threshold voltage of the drive transistor T3.

As can be seen from the formula, a magnitude of the drive current I is related to the threshold voltage Vth of the drive transistor T3, and the magnitude of the drive current I determines the light-emitting brightness of the light-emitting element 13. Therefore, a magnitude of the threshold voltage Vth of the drive transistor T3 affects the light-emitting brightness of the light-emitting element 13.

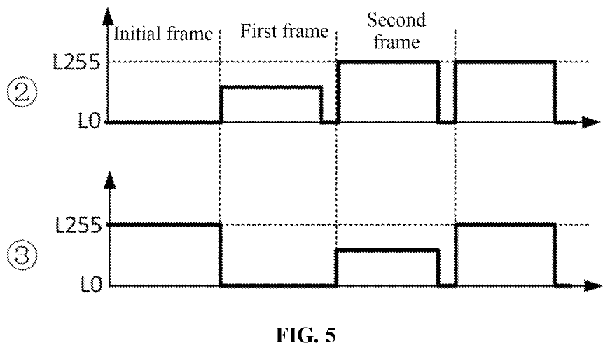

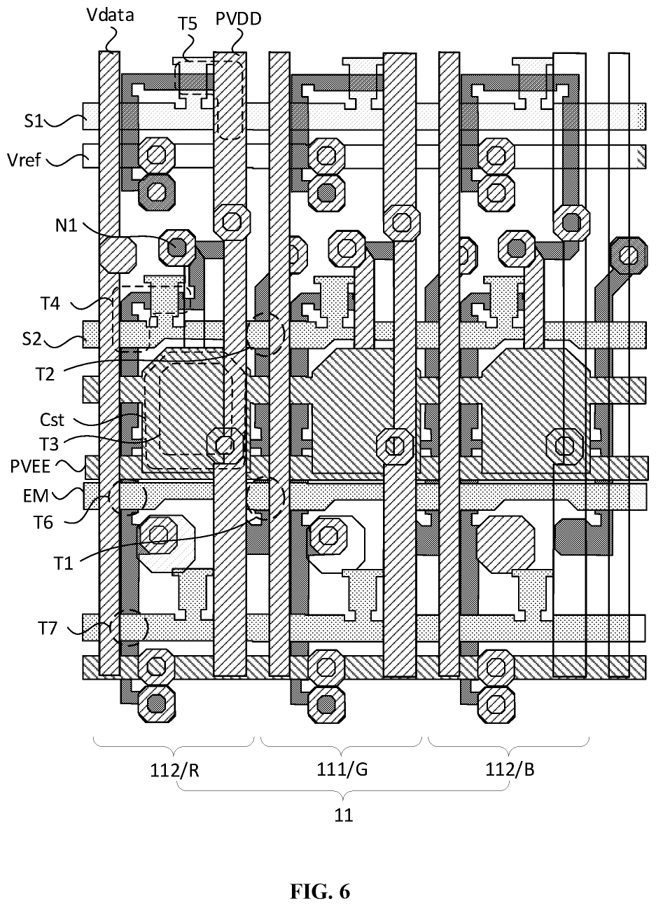

FIG. 4 is a schematic view of a dragging shadow phenomenon of a display panel according to an embodiment of the present disclosure, and FIG. 5 is schematic view showing a color scale of part of pixel cells of FIG. 4. Exemplarily, as shown in FIGS. 4 and 5, the color scales desired to displayed by a first pixel cell \textcircled{1}, a second pixel cell \textcircled{2}, a third pixel cell \textcircled{3} and a fourth pixel cell \textcircled{4} at an initial frame, a first frame and a second frame are as follows.

For the first pixel cell \textcircled{1}: L255/white (initial frame)+L255/white (first frame)+L255/white (second frame).

For the second pixel cell \textcircled{2}: L0/black (initial frame)+L255/white (first frame)+L255/white (second frame).

For the third pixel cell \textcircled{3}: L255/white (initial frame)+L0/black (first frame)+L255/white (second frame).

For the fourth pixel cell \textcircled{4}: L255/white (initial frame)+L255/white (first frame)+L0/black (second frame).

However, there is a hysteresis effect in the threshold voltage Vth of the drive transistor T3, and the hysteresis effect means that the magnitude of the threshold voltage Vth of the drive transistor T3 varies with the gate voltage of the drive transistor T3.

When a black picture is switched to a white picture, the gate voltage of the drive transistor T3 is converted from a gate voltage corresponding to the black picture to a gate voltage corresponding to the white picture, but the threshold voltage Vth of the drive transistor T3 is delayed to be changed, so that the threshold voltage Vth of the drive transistor T3 remains at a threshold voltage Vth corresponding to a gate voltage of the black picture at a first frame that the black picture is switched to the white picture. As described above, the magnitude of the threshold voltage Vth of the drive transistor T3 may affect the light-emitting brightness of the light-emitting element 13. Therefore, at the first frame that the black picture is switched to the white picture, the threshold voltage Vth of the drive transistor T3 is not converted to a threshold voltage Vth corresponding to a gate voltage of the white picture in time, which causes the pixel cell to not reach the required brightness at the first frame that the black picture is switched to the white picture, that is, the pixel cell cannot reach a L255 gray scale brightness upon just switching from a L0 gray scale to the L255 gray scale, thereby causing the pixel cell to have a problem of dim brightness compared to a pixel cell showing the L255 gray scale at periphery. When the white picture is switched to the white picture at a next frame, the threshold voltage Vth of the drive transistor T3 has been switched to the threshold voltage Vth corresponding to the gate voltage of the white picture. At this time, the pixel cell may reach the L255 gray scale brightness, and the light-emitting brightness of the pixel cell is consistent with that of the pixel cell showing the L255 gray scale at periphery. As can be seen from the above process, when the black picture is switched to the white picture, there may be the dim brightness for short time (1 frame), thereby generating a dragging shadow.

At the same time, light-emitting elements 13 of different colors may make sub-pixels of different colors differ in the brightness attenuation at the first frame that the black picture is switched to the white picture due to different light-emitting layer materials, so that the brightness of the sub-pixels of different colors is inconsistent, and as a result, the pixel unit may have a problem of color shift in the visual effect at the first frame that the black picture is switched to the white picture. At the first frame that the black picture is switched to the white picture, red sub-pixels are brighter, and green sub-pixels are darker, so that a picture at the first frame that the black picture is switched to the white picture is more reddish, the user observes the reddish lagging shadow when viewing, and the reddish lagging shadow will make the human eye feel the heavier lagging shadow degree in the visual effect, thereby affecting the display effect of the display panel.

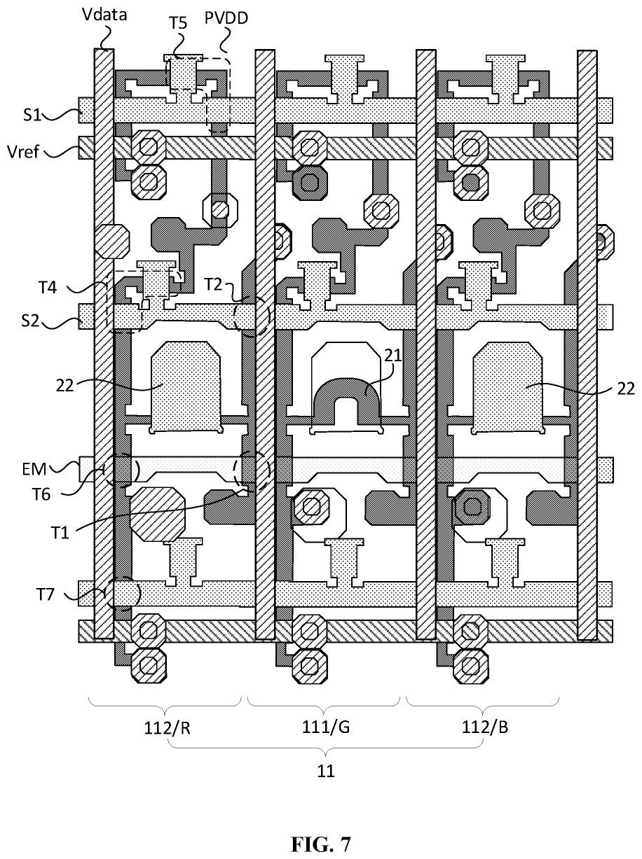

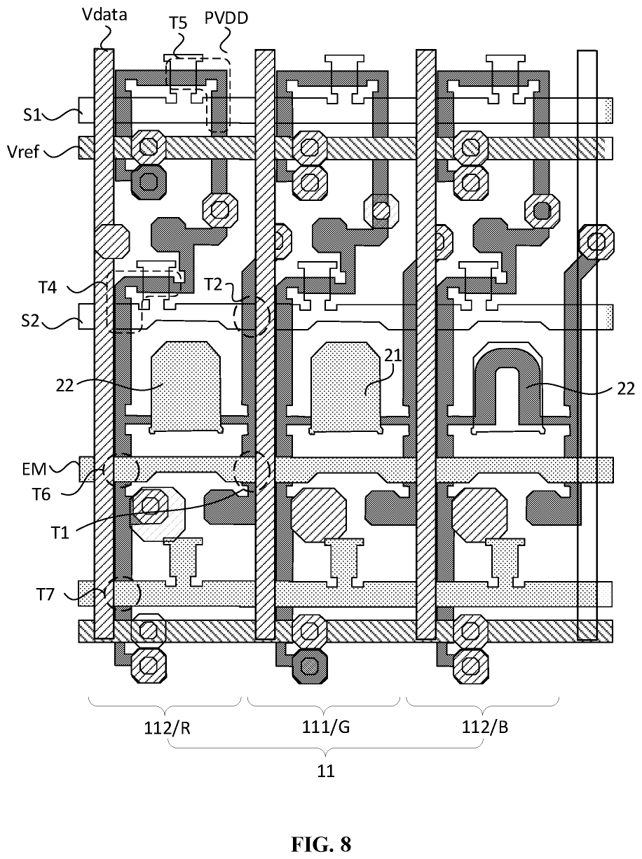

Based on the above problems, FIG. 6 is a schematic structural view of a pixel circuit according to an embodiment of the present disclosure, and FIG. 7 is a schematic view showing a partial structure of the pixel circuit of FIG. 6. FIG. 6 shows a pixel circuit in one pixel cell 10. In FIG. 7, part of structures is hidden on the basis of FIG. 6 in order to clearly illustrate the improved structure of the present application.

As shown in FIGS. 1, 2, 6, and 7, in the pixel cell 10, the first sub-pixel 111 is configured to emit green light, the second sub-pixel 112 is configured to emit red light and/or blue light, the drive transistor T3 in the first sub-pixel 111 has the first channel 21, the drive transistor T3 in the second sub-pixel 112 has the second channel 22, and in this embodiment, the width-to-length ratio of the first channel 21 is greater than the width-to-length ratio of the second channel 22.

Here, the active layer 01 of the drive transistor T3 may include a source region, a drain region, and a channel located between the source region and the drain region. In a thickness direction of the display panel, it should be considered that a region in which the gate layer 02 of the drive transistor T3 overlaps the active layer 01 of the drive transistor T3 is a channel region, the channel has a semiconductor characteristic, and a width-to-length ratio of the channel refers to a ratio of a channel width to a channel length.

The width-to-length ratio of the channel in the drive transistor T3 is the larger, a difference between a gate voltage corresponding to the black picture of the drive transistor T3 and a gate voltage corresponding to the white picture of the drive transistor T3 is the smaller, then a difference between a threshold voltages Vth corresponding to the gate voltage of the black picture of the drive transistor T3 and a threshold voltages Vth corresponding to the gate voltage of the white picture of the drive transistor T3 is the smaller. A difference between a threshold voltages Vth corresponding to the black picture of the drive transistor T3 and a threshold voltages Vth corresponding to the white picture of the drive transistor T3 is the smaller, when the black picture is switched to the white picture, the threshold voltage Vth of the drive transistor T3 is more easily to reach the threshold voltage Vth corresponding to the gate voltage of the white picture, so that the brightness of the first frame of the white picture is more easily restored to the brightness required for the white picture, and the brightness of the first frame of the corresponding white picture is relatively brighter.

Conversely, if the width-to-length ratio of the channel in the drive transistor T3 is the smaller, a difference between a gate voltage corresponding to the black picture of the drive transistor T3 and a gate voltage corresponding to the white picture of the drive transistor T3 is the larger, then a difference between a threshold voltages Vth corresponding to the gate voltage of the black picture of the drive transistor T3 and a threshold voltages Vth corresponding to the gate voltage of the white picture of the drive transistor T3 is the larger. A difference between a threshold voltages Vth corresponding to the black picture of the drive transistor T3 and a threshold voltages Vth corresponding to the white picture of the drive transistor T3 is the larger, when the black picture is switched to the white picture, the threshold voltage Vth of the drive transistor T3 is more difficult to reach the threshold voltage Vth corresponding to the gate voltage of the white picture, so that the brightness of the first frame of the white picture is more difficult restored to the brightness required for the white picture, and the brightness of the first frame of the corresponding white picture is relatively darker.

Based on the above finding, in this embodiment, the width-to-length ratio of the first channel 21 in the first sub-pixel 111 emitting the green light is set to be greater than the width-to-length ratio of the second channel 22 in the second sub-pixel 112 emitting the red light and/or the blue light, so that when the black picture is switched to the white picture, the threshold voltage Vth of the drive transistor T3 in the first sub-pixel 111 is more easily to reach the threshold voltage Vth corresponding to the gate voltage of the white picture, whereas the threshold voltage Vth of the drive transistor T3 in the second sub-pixel 112 is more difficult to reach to the threshold voltage Vth corresponding to the gate voltage of the white picture, whereby the brightness of the first sub-pixel 111 is increased in the first frame of the white picture, the brightness of the second sub-pixel 112 is reduced in the first frame of the white picture, so as to compensate for the green light brightness in the first frame of the white picture, improve the phenomenon of the image redness in the first frame of the white picture, and further improve the problem of the color redness caused by a dragging shadow to enable the dragging shadow color observed by the user to be corrected, reduce the severity of the dragging shadow in the visual effect, and thus improve the display effect of the display panel.

It should be noted that specific width-to-length ratios of the first channel 21 and the second channel 22 are not specifically limited in the embodiments of the present disclosure, and it is only necessary to satisfy that the width-to-length ratio of the first channel 21 in the first sub-pixel 111 emitting the green light is greater than the width-to-length ratio of the second channel 22 in the second sub-pixel 112 emitting the red light and/or the blue light.

In summary, according to the display panel provided in the embodiments of the present disclosure, the width-to-length ratio of the first channel of the drive transistor in the first sub-pixel emitting the green light is set to be greater than the width-to-length ratio of the second channel of the drive transistor in the second sub-pixel emitting the red light and/or the blue light, so that when the black picture is switched to the white picture, the threshold voltage of the drive transistor in the first sub-pixel is more easily to reach the threshold voltage corresponding to the gate voltage of the white picture, whereas the threshold voltage of the drive transistor in the second sub-pixel is more difficult to reach to the threshold voltage corresponding to the gate voltage of the white picture, whereby the brightness of the first sub-pixel is increased in the first frame of the white picture, the brightness of the second sub-pixel is reduced in the first frame of the white picture, so as to compensate for the green light brightness in the first frame of the white picture, improve the phenomenon of the image redness in the first frame of the white picture, and further improve the problem of the color redness caused by a dragging shadow to enable the dragging shadow color observed by the user to be corrected, reduce the severity of the dragging shadow in the visual effect, and thus improve the display effect of the display panel.

With continued reference to FIG. 7, optionally, a width of the first channel 21 is the same as a width of the second channel 22, and a length of the first channel 21 is less than a length of the second channel 22.

Here, it is to be understood that the width-to-length ratio of the channel in the drive transistor T3 is a ratio of the channel width of the drive transistor T3 to the channel length of the drive transistor T3.

In this embodiment, as shown in FIG. 7, the first channel 21 of the drive transistor T3 in the first sub-pixel 111 emitting the green light is compared to the second channel 22 of the drive transistor T3 in the second sub-pixel 112 emitting the red light and/or the blue light, the width of the first channel 21 is the same as the width of the second channel 22, and the length of the first channel 21 is less than the length of the second channel 22, so that the width-to-length ratio of the first channel 21 is greater than the width-to-length ratio of the second channel 22, and further so that when the black picture is switched to the white picture, the threshold voltage Vth of the drive transistor T3 in the first sub-pixel 111 is more easily to reach the threshold voltage Vth corresponding to the gate voltage of the white picture, whereas the threshold voltage Vth of the drive transistor T3 in the second sub-pixel 112 is more difficult to reach to the threshold voltage Vth corresponding to the gate voltage of the white picture, whereby the brightness of the first sub-pixel 111 is increased in the first frame of the white picture, the brightness of the second sub-pixel 112 is reduced in the first frame of the white picture, so as to compensate for the green light brightness in the first frame of the white picture, improve the phenomenon of the image redness in the first frame of the white picture to enable the dragging shadow color observed by the user to be corrected, and reduce the severity of the dragging shadow in the visual effect.

The channel width of the drive transistor T3 in the first sub-pixel 111 is set to be the same as the channel width of the drive transistor T3 in the second sub-pixel 112, the channel length of the drive transistor T3 in the first sub-pixel 111 and the channel length of the drive transistor T3 in the second sub-pixel 112 are adjusted so that the width-to-length ratio of the first channel 21 is greater than the width-to-length ratio of the second channel 22, which helps to make the adjustment of the width-to-length ratio of the channel of the drive transistor T3 finer and to correct the tagging shadow color observed by the user more accurately.

FIG. 8 is a schematic view showing a partial structure of a pixel circuit according to an embodiment of the present disclosure. As shown in FIG. 8, optionally, the length of the first channel 21 is the same as the length of the second channel 22, and the width of the first channel 21 is greater than the width of the second channel 22.

In this embodiment, as shown in FIG. 8, the first channel 21 of the drive transistor T3 in the first sub-pixel 111 emitting the green light is compared to the second channel 22 of the drive transistor T3 in the second sub-pixel 112 emitting the red light and/or the blue light, the length of the first channel 21 is the same as the length of the second channel 22, and the width of the first channel 21 is greater than the width of the second channel 22, that is, the channel length of the drive transistor T3 in the first sub-pixel 111 is set to be the same as the channel length of the drive transistor T3 in the second sub-pixel 112, the channel width of the drive transistor T3 in the first sub-pixel 111 and the channel width of the drive transistor T3 in the second sub-pixel 112 are adjusted so that the width-to-length ratio of the first channel 21 is greater than the width-to-length ratio of the second channel 22, and further so that when the black picture is switched to the white picture, the threshold voltage Vth of the drive transistor T3 in the first sub-pixel 111 is more easily to reach the threshold voltage Vth corresponding to the gate voltage of the white picture, whereas the threshold voltage Vth of the drive transistor T3 in the second sub-pixel 112 is more difficult to reach to the threshold voltage Vth corresponding to the gate voltage of the white picture, whereby the brightness of the first sub-pixel 111 is increased in the first frame of the white picture, the brightness of the second sub-pixel 112 is reduced in the first frame of the white picture, so as to compensate for the green light brightness in the first frame of the white picture, improve the phenomenon of the image redness in the first frame of the white picture to enable the dragging shadow color observed by the user to be corrected, and reduce the severity of the dragging shadow in the visual effect.

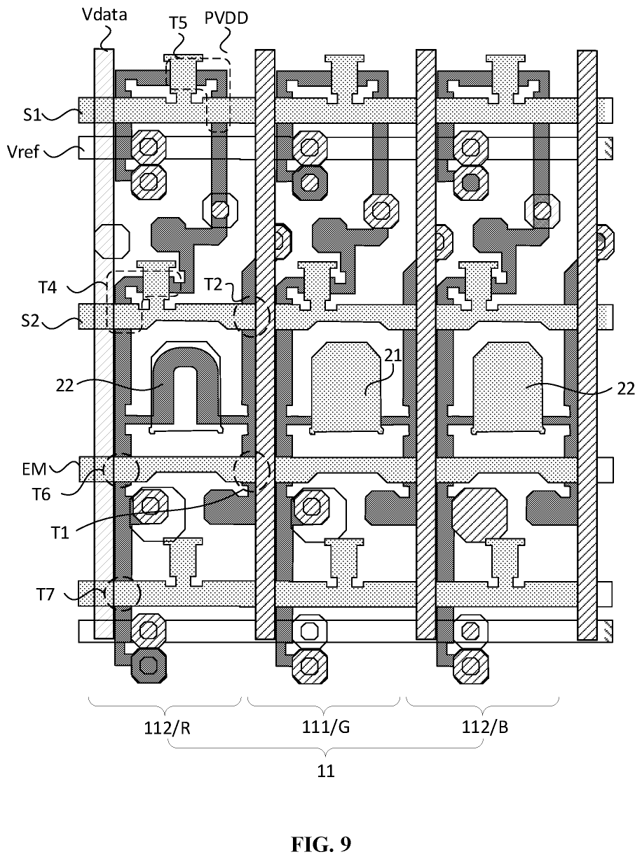

FIG. 9 is a schematic view showing a partial structure of another pixel circuit according to an embodiment of the present disclosure. As shown in FIG. 9, optionally, the length of the first channel 21 is less than the length of the second channel 22, and the width of the first channel 21 is greater than the width of the second channel 22.

In this embodiment, as shown in FIG. 9, the first channel 21 of the drive transistor T3 in the first sub-pixel 111 emitting the green light is compared to the second channel 22 of the drive transistor T3 in the second sub-pixel 112 emitting the red light and/or the blue light, the length of the first channel 21 is less than the length of the second channel 22, and the width of the first channel 21 is greater than the width of the second channel 22, that is, the channel width of the drive transistor T3 in the first sub-pixel 111 and the channel width of the drive transistor T3 in the second sub-pixel 112, as well as the channel length of the drive transistor T3 in the first sub-pixel 111 and the channel length of the drive transistor T3 in the second sub-pixel 112 are adjusted simultaneously so that the width-to-length ratio of the first channel 21 is greater than the width-to-length ratio of the second channel 22, and further so that when the black picture is switched to the white picture, the threshold voltage Vth of the drive transistor T3 in the first sub-pixel 111 is more easily to reach the threshold voltage Vth corresponding to the gate voltage of the white picture, whereas the threshold voltage Vth of the drive transistor T3 in the second sub-pixel 112 is more difficult to reach to the threshold voltage Vth corresponding to the gate voltage of the white picture, whereby the brightness of the first sub-pixel 111 is increased in the first frame of the white picture, the brightness of the second sub-pixel 112 is reduced in the first frame of the white picture, so as to compensate for the green light brightness in the first frame of the white picture, improve the phenomenon of the image redness in the first frame of the white picture to enable the dragging shadow color observed by the user to be corrected, and reduce the severity of the dragging shadow in the visual effect.

It should be noted that the length and the width of the first channel 21 of the drive transistor T3 in the first sub-pixel 111 and the length and the width of the second channel 22 of the drive transistor T3 in the second sub-pixel 112 emitting the red light and/or the blue light are not specifically limited in the embodiments of the present disclosure, and it is only necessary to satisfy that the width-to-length ratio of the first channel 21 in the first sub-pixel 111 emitting the green light is greater than the width-to-length ratio of the second channel 22 in the second sub-pixel 112 emitting the red light and/or the blue light.

With continued reference to FIGS. 7 to 9, optionally, a shape of the first channel 21 includes a U-shape, and a shape of the second channel 22 includes a U-shape.

As shown in FIG. 7, the shape of the first channel 21 and the shape of the second channel 22 are disposed to be U-shape, so that a longer channel may be provided in a limited space than a straight-line channel, whereby more adjustment space may be provided for width-to-length ratio of the channel to satisfy the correction requirement of the dragging shadow color.

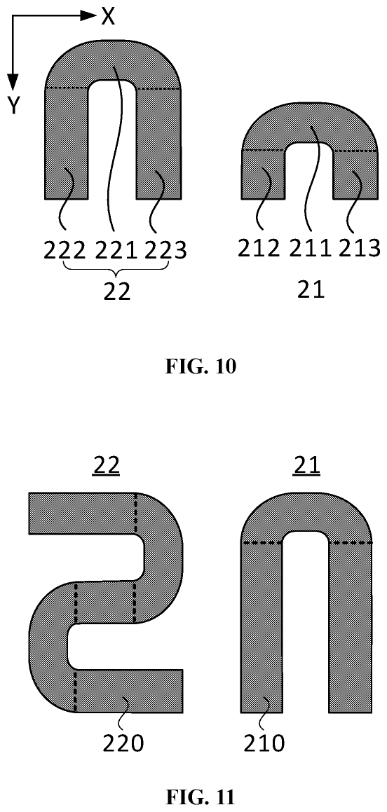

FIG. 10 is a schematic structural view of a first channel and a second channel according to an embodiment of the present disclosure. As shown in FIG. 10, optionally, the first channel 21 includes a first segment 211, a second segment 212 connected to one end of the first segment 211, and a third segment 213 connected to another end of the first segment 211. An extension direction of the second segment 212 is the same as an extension direction of the third segment 213, the extension direction of the second segment 212 intersects an extension direction of the first segment 211, and a length of the second segment 212 is the same as a length of the third segment 213. The second channel 22 includes a fourth segment 221, a fifth segment 222 connected to one end of the fourth segment 221, and a sixth segment 223 connected to another end of the fourth segment 221. An extension direction of the fifth segment 222 is the same as an extension direction of the sixth segment 223, the extension direction of the fifth segment 222 intersects an extension direction of the fourth segment 221, and a length of the fifth segment 222 is the same as a length of the sixth segment 223. A length of the first segment 211 is the same as a length of the fourth segment 221, and the length of the second segment 212 is less than the length of the fifth segment 222.

Exemplarily, as shown in FIG. 4, the shapes of the first channel 21 and the second channel 22 are both U-shape, the first segment 211 of the first channel 21 and the fourth segment 221 of the second channel 22 extend in a first direction X, the second segment 212 and the third segment 213 of the first channel 21 as well as the fifth segment 222 and the sixth segment 223 of the second channel 22 extend in a second direction Y, where the first direction X is perpendicular to the second direction Y, but not limited thereto. In other embodiments, it is only necessary to satisfy that the first direction X intersects the second direction Y.

Further, the length of the first segment 211 of the first channel 21 is the same as the length of the fourth segment 221 of the second channel 22. In this case, a width of the first channel 21 in the first direction X is the same as a width of the second channel 22 in the first direction X, so that the drive transistor T3 may have the same size in the first direction X. The length of the second segment 212 of the first channel 21 is the same as the length of the third segment 213 of the first channel 21, and the length of the fifth segment 222 of the second channel 22 is the same as the length of the sixth segment 223 of the second channel 22, which helps to make the space size occupied by the drive transistor T3 in the second direction Y smaller.

It is to be understood that the length of the first channel 21 is a sum of the lengths of the first segment 211, the second segment 212 and the third segment 213, and the length of the second channel 22 is a sum of the lengths of the fourth segment 221, the fifth segment 222 and the sixth segment 223. In this embodiment, the length of the second segment 212 is set to be less than the length of the fifth segment 222, so that the length of the first channel 21 is less than the length of the second channel 22, the width-to-length ratio of the first channel 21 is greater than the width-to-length ratio of the second channel 22, and further so that when the black picture is switched to the white picture, the threshold voltage Vth of the drive transistor T3 in the first sub-pixel 111 is more easily to reach the threshold voltage Vth corresponding to the gate voltage of the white picture, whereas the threshold voltage Vth of the drive transistor T3 in the second sub-pixel 112 is more difficult to reach to the threshold voltage Vth corresponding to the gate voltage of the white picture, whereby the brightness of the first sub-pixel 111 is increased in the first frame of the white picture, the brightness of the second sub-pixel 112 is reduced in the first frame of the white picture, so as to compensate for the green light brightness in the first frame of the white picture, improve the phenomenon of the image redness in the first frame of the white picture to enable the dragging shadow color observed by the user to be corrected, and reduce the severity of the dragging shadow in the visual effect.

In the schemes provided in this embodiment, since the length of the second segment 212 of the first channel 21 is the same as the length of the third segment 213 of the first channel 21, and the length of the fifth segment 222 of the second channel 22 is the same as the length of the sixth segment 223 of the second channel 22, therefore, the length of the channel may be adjusted greatly by only changing the lengths of the first channel 21 and the second channel 22 in the second direction Y, so that the width-length ratio of the first channel 21 is greater than the width-length ratio of the second channel 22, which is simple in scheme and easy to implement.

FIG. 11 is a schematic structural view of another first channel and another second channel according to an embodiment of the present disclosure. As shown in FIG. 11, optionally, the first channel 21 includes n first fold line segments 210 connected in sequence, and two connected first fold line segments 210 among the n first fold line segments have different extension directions. The second channel 22 includes m second fold line segments 220 connected in sequence, and two connected second fold line segments 220 among the m second fold line segments have different extension directions, where 0<n<m, and n and m are both positive integers.

Exemplarily, as shown in FIG. 11, the first channel 21 is formed by at least two first fold line segments 210 connected in sequence, two connected first fold line segments 210 have different extension directions, so that the first channel 21 is in the form of a fold line. Similarly, the second channel 22 is formed by at least two second fold line segments 220 connected in sequence, two connected second fold line segments 220 have different extension directions, so that the second channel 22 is in the form of a fold line. The fold-line channel advantageously occupies a smaller space size than the straight-line channel, thereby helping to increase the density of the pixel circuit and improve the display resolution of the display panel.

With continued reference to FIG. 11, in this embodiment, a number n (n=3 is used as an example in FIG. 11) of first fold line segments 210 in the first channel 21 is set to be less than a number m (m=5 is used as an example in FIG. 11) of the second fold line segments 220 in the second channel 22, so that the second channel 22 have a longer length in a limited space, whereby the length of the second channel 22 is made greater than the length of the first channel 21 without additionally increasing the space size occupied by the second channel 22, and further the width-to-length ratio of the first channel 21 is made greater than the width-to-length ratio of the second channel 22.

Here, numerical values of n and m are not specifically limited in the embodiments of the present disclosure, only 0<n<m needs to be satisfied, and both n and m are positive integers.

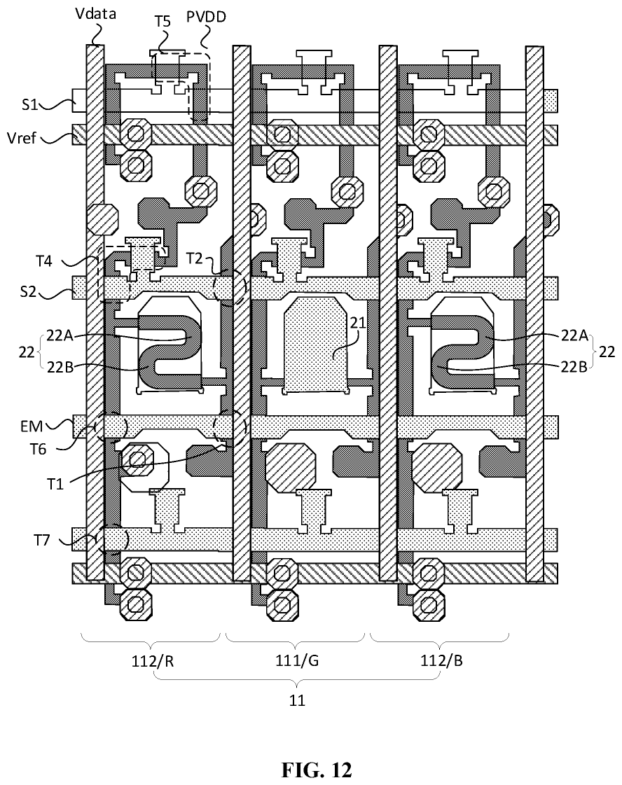

FIG. 12 is a schematic view showing a partial structure of still another pixel circuit according to an embodiment of the present disclosure. A shape of the first channel 21 includes a U-shape, a shape of the second channel 22 includes a dual U-shape, the dual U-shape includes a first U-shaped portion 22A and a second U-shaped portion 22B, the first U-shaped portion 22A and the second U-shaped portion 22B share a same side, and an opening direction of the first U-shaped portion 22A is different from an opening direction of the second U-shaped portion 22B.

Specifically, as shown in FIG. 12, the first channel 21 is configured to be U-shape, compared with the straight-line channel, the U-shaped first channel 21 is conductive to occupying the smaller size space under the same channel length, thereby helping to increase the density of the pixel circuit and improve the display resolution of the display panel.

Meanwhile, the shape of the second channel 22 is configured to be dual U-shape, i.e., the first U-shaped portion 22A and the second U-shaped portion 22B which are dual U-shape and have opposite opening directions, and the first U-shaped portion 22A and the second U-shaped portion 22B share the same side, whereby the second channel 22 has a larger number of folds than the first channel 21, so that the second channel 22 can have a longer length without additionally increasing the space size occupied by the second channel 22, the length of the second channel 22 is greater than the length of the first channel 21, and further the width-to-length ratio of the first channel 21 is greater than the width-to-length ratio of the second channel 22.

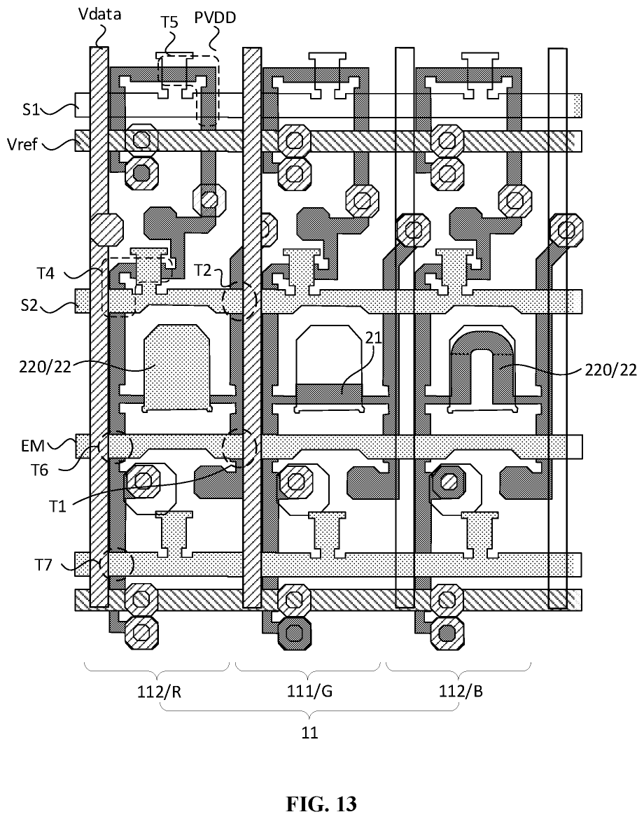

FIG. 13 is a schematic structural view of still another first channel and still another second channel according to an embodiment of the present disclosure. As shown in FIG. 13, optionally, a shape of the first channel 21 includes a straight line, and the second channel 22 includes at least two second fold line segments 220 connected in sequence, and two connected second fold line segments 220 have different extensions.

Exemplarily, as shown in FIG. 13, the first channel 21 may be provided in a straight line, to help make the first channel 21 shorter in length, thereby achieving a greater width-to-length ratio. At the same time, the second channel 22 is configured to be formed by at least two second fold line segments 220 connected in sequence, and the two connected second fold line segments 220 have different extension directions, so that the second channel 22 is in the form of a fold line. Compared with the straight-line channel, the fold-line channel is advantageous in achieving a longer channel length within a smaller space size, thereby achieving a smaller width-to-length ratio, and further achieving that the width-to-length ratio of the first channel 21 is greater than the width-to-length ratio of the second channel 22.

With continued reference to FIG. 3, optionally, a capacitance of the light-emitting element 13 in the first sub-pixel 111 is less than a capacitance of the light-emitting element 13 in the second sub-pixel 112.

As shown in FIG. 3, in a light-emitting stage, a current path is formed from the first power supply signal line PVDD, the drive transistor T3 and the light-emitting element 13 to the second power supply signal line PVEE, so that the drive current generated by the drive transistor T3 is supplied to the light-emitting element 13 to drive the light-emitting element 13 to emit light.

In the related art, the light-emitting element 13 for emitting green light has a relatively large capacitance, that is, the capacitance of the light-emitting element 13 in the first sub-pixel 111 is relatively large, so that when the black picture is switched to the white picture, the capacitance of the light-emitting element 13 in the first sub-pixel 111 is charged for a longer period of time within the first frame of the white picture. Since the capacitance of the light-emitting element 13 in the first sub-pixel 111 does not emit light before being filled, the capacitance of the light-emitting element 13 in the first sub-pixel 111 is charged for a longer period of time during the limited duration of the light-emitting stage within one frame, whereby a duration in which the light-emitting element 13 in the first sub-pixel 111 emits light is shortened, thereby reducing the brightness output by the light-emitting element 13 in the first sub-pixel 111 at the first frame of the white picture.

Correspondingly, in the related art, the light-emitting element 13 for emitting red light and/or blue light has a relatively small capacitance, that is, the capacitance of the light-emitting element 13 in the second sub-pixel 112 is relatively small, so that when the black picture is switched to the white picture, the capacitance of the light-emitting element 13 in the second sub-pixel 112 is charged only in a short period of time within the first frame of the white picture. In this way, more time may be used for the light emission of the light-emitting element 13 in the second sub-pixel 112 during the limited duration of the light-emitting stage within one frame, so that the brightness output by the light-emitting element 13 in the second sub-pixel 112 at the first frame of the white picture is relatively high.

As described above, in the related art, when the black picture is switched to the white picture, due to the difference in capacitances of the light-emitting element 13 in the sub-pixels of different colors, a light-emitting duration of the light-emitting element 13 in the first sub-pixel 111 within the first frame of the white picture is relatively short, and a light-emitting duration of the light-emitting element 13 in the second sub-pixel 112 within the first frame of the white picture is relatively long, so that a problem that the green light in the first frame of the white picture is relatively dark and the red light in the first frame of the white picture is relatively bright may be aggravated, whereby the picture at the first frame that the black picture is switched to the white picture is more reddish, the user observes the reddish lagging shadow when viewing, and the reddish lagging shadow will make the human eye feel the heavier lagging shadow degree in the visual effect, thereby affecting the display effect of the display panel.

Based on the above problem, in this embodiment, the capacitance of the light-emitting element 13 in the first sub-pixel 111 is set to be less than the capacitance of the light-emitting element 13 in the second sub-pixel 112, so that when the black picture is switched to the white picture, the light-emitting element 13 in the second sub-pixel 112 is charged for a longer period of time within the first frame of the white picture, and the light-emitting element 13 in the first sub-pixel 111 is charged for a shorter period of time within the first frame of the white picture, whereby the light-emitting element 13 in the first sub-pixel 111 emits light for a longer duration and the light-emitting element 13 in the second sub-pixel 112 emits light for a shorter duration within the first frame of the white picture, thereby increasing the brightness output by the first sub-pixel 111 in the first frame of the white picture, reducing the brightness output by the second sub-pixel 112 in the first frame of the white picture, so as to compensate for the green light brightness in the first frame of the white picture, improve the phenomenon of the image redness in the first frame of the white picture, and further improve the problem of the color redness caused by a dragging shadow to enable the dragging shadow color observed by the user to be corrected, reduce the severity of the dragging shadow in the visual effect, and thus improve the display effect of the display panel.

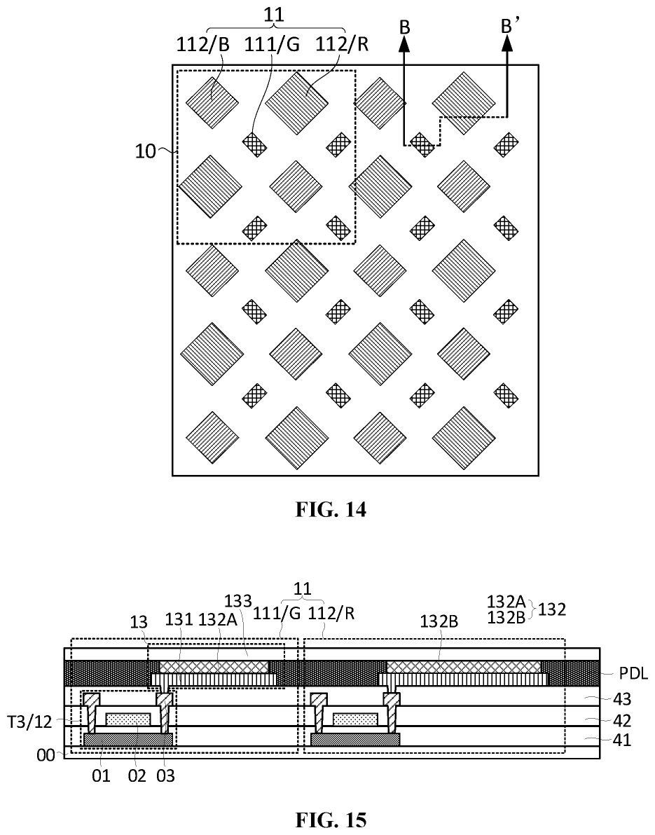

FIG. 14 is a schematic structural view of another display panel according to an embodiment of the present disclosure, and FIG. 15 is schematic structural cross-sectional view of FIG. 14 taken along a direction of B-B′. As shown in FIGS. 14 and 15, optionally, the display panel according to the embodiment of the present disclosure includes a base substrate 00. The light-emitting element 13 includes an anode layer 131, a light-emitting layer 132 and a cathode layer 133, which are sequentially stacked and arranged on a side of the base substrate 00. The light-emitting layer 132 of the light-emitting element 13 in the first sub-pixel 111 is a first light-emitting layer 132A, the light-emitting layer 132 of the light-emitting element 13 in the second sub-pixel 112 is a second light-emitting layer 132B, and an area of the first light-emitting layer 132A is less than an area of the second light-emitting layer 132B.

An area of the light-emitting layer 132 in the light-emitting element 13 is the larger, and a capacitance of the light-emitting element 13 is the larger.

Therefore, as shown in FIG. 14 and FIG. 15, in this embodiment, the area of the first light-emitting layer 132A of the light-emitting element 13 in the first sub-pixel 111 emitting the green light is set to be less than the area of the second light-emitting layer 132B of the light-emitting element 13 in the second sub-pixel 112 emitting the red light and/or the blue light, so that the capacitance of the light-emitting element 13 in the first sub-pixel 111 is less than the capacitance of the light-emitting element 13 in the second sub-pixel 112, and further so that when the black picture is switched to the white picture, the light-emitting element 13 in the first sub-pixel 111 is charged for a shorter period of time within the first frame of the white picture, and the light-emitting element 13 in the second sub-pixel 112 is charged for a longer period of time within the first frame of the white picture, whereby the light-emitting element 13 in the first sub-pixel 111 emits light for a longer duration and the light-emitting element 13 in the second sub-pixel 112 emits light for a shorter duration within the first frame of the white picture, thereby increasing the brightness output by the first sub-pixel 111 in the first frame of the white picture, reducing the brightness output by the second sub-pixel 112 in the first frame of the white picture, so as to compensate for the green light brightness in the first frame of the white picture, improve the phenomenon of the image redness in the first frame of the white picture, and further improve the problem of the color redness caused by a dragging shadow to enable the dragging shadow color observed by the user to be corrected, reduce the severity of the dragging shadow in the visual effect, and thus improve the display effect of the display panel.

With continued reference to FIG. 15, the light-emitting layer 132 of each light-emitting element 13 is separated by a pixel definition layer PDL. The pixel definition layer PDL includes multiple openings, the light-emitting layer 132 is located within the openings, and a region in which the openings of the pixel definition layer PDL are located is a light-emitting region of the light-emitting element 13. In this embodiment, the area of the light-emitting layer 132 in the openings can be adjusted by adjusting areas of the openings of the pixel definition layer PDL.

It should be noted that the area of the first light-emitting layer 132A and the area of the second light-emitting layer 132B are not specifically limited in the embodiments of the present disclosure, and it is only necessary to satisfy that the area of the first light-emitting layer 132A is less than the area of the second light-emitting layer 132B.

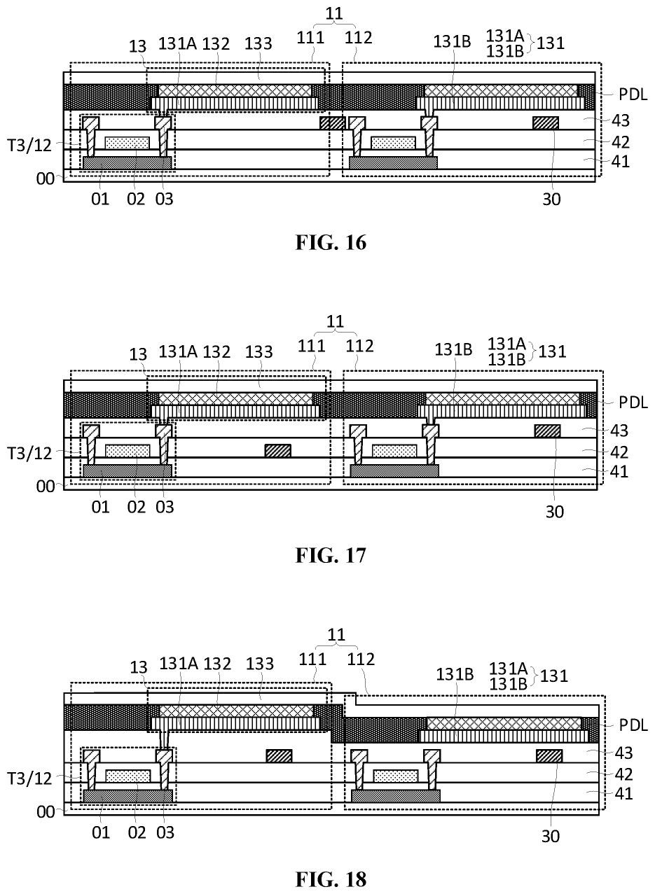

FIG. 16 is a schematic view showing a partial cross-sectional structure of a display panel according to an embodiment of the present disclosure. As shown in FIG. 16, optionally, the display panel according to the embodiment of the present disclosure includes a base substrate 00 and multiple signal traces 30. The light-emitting element 13 includes an anode layer 131, a light-emitting layer 132 and a cathode layer 133 which are sequentially stacked and arranged on a side of the base substrate 00. The anode layer 131 of the light-emitting element 13 in the first sub-pixel 111 is a first anode layer 131A, and the anode layer 131 of the light-emitting element 13 in the second sub-pixel 112 is a second anode layer 131B. In a thickness direction of the display panel, an overlapping area of the first anode layer 131A and a signal trace 30 is less than an overlapping area of the second anode layer 131B and a signal trace 30.

Here, the display panel includes multiple signal traces 30 arranged on a side of the base substrate 00, and the signal traces 30 are configured to provide signals required for display for the pixel circuits to achieve the image display. As shown in FIGS. 3 and 6, the signal trace 30 may include at least one of a first power supply signal line PVDD, a second power supply signal line PVEE, a first scan signal line S1, a reference signal line Vref, a second scan signal line S2, a data signal line Vdata, or a light-emitting control signal line EM, which are not specifically limited in the embodiments of the present disclosure.

With continued reference to FIG. 3, when the black picture is switched to the white picture, a duration for charging the capacitance in the light-emitting stage within the first frame of the white frame depends on a total capacitance between an N4 node (i.e., the anode layer 131 of the light-emitting element 13) and the second power signal line PVEE. That is, the total capacitance between the N4 node and the second power supply signal line PVEE is the larger, the capacitance is charged for a longer period of time within the first frame of the white picture when the black picture is switched to the white picture, then a duration during which the light emitting element 13 emits light is shortened during the limited duration of the light-emitting stage within one frame, and the brightness output by the light-emitting element 13 in the first frame of the white picture is the darker. A parasitic capacitance formed at the N4 node will affect the total capacitance between the N4 node and the second power supply signal line PVEE, that is, the parasitic capacitance formed at the N4 node is the greater, then the total capacitance between the N4 node and the second power supply signal line PVEE is the greater.

In this embodiment, as shown in FIG. 16, in the thickness direction of the display panel, the overlapping area between the first anode layer 131A of the light-emitting element 13 in the first sub-pixel 111 emitting the green light and the signal trace 30 is set to be less than the overlapping area between the second anode layer 131B of the light-emitting element 13 in the second sub-pixel 112 emitting the red light and/or the blue light and the signal trace 30, so that the parasitic capacitance formed between the first anode layer 131A of the light-emitting element 13 in the first sub-pixel 111 and the signal trace 30 is relatively small, whereas the parasitic capacitance formed between the second anode layer 131B of the light-emitting element 13 in the second sub-pixel 112 and the signal trace 30 is relatively large, that is, a smaller parasitic capacitance is formed at the N4 node in the first sub-pixel 111, and a larger parasitic capacitance is formed at the N4 node in the second sub-pixel 112, whereby when the black picture is switched to the white picture, and the parasitic capacitance at the N4 node in the first sub-pixel 111 is charged for a shorter period of time within the first frame of the white picture, the parasitic capacitance at the N4 node in the second sub-pixel 112 is charged for a longer period of time within the first frame of the white picture, and further, the light-emitting element 13 in the first sub-pixel 111 emits light for a longer duration and the light-emitting element 13 in the second sub-pixel 112 emits light for a shorter duration within the first frame of the white picture, thereby increasing the brightness output by the first sub-pixel 111 in the first frame of the white picture, reducing the brightness output by the second sub-pixel 112 in the first frame of the white picture, so as to compensate for the green light brightness in the first frame of the white picture, improve the phenomenon of the image redness in the first frame of the white picture, and further improve the problem of the color redness caused by a dragging shadow to enable the dragging shadow color observed by the user to be corrected, reduce the severity of the dragging shadow in the visual effect, and thus improve the display effect of the display panel.

FIG. 17 is a schematic view showing a partial cross-sectional structure of another display panel according to an embodiment of the present disclosure. As shown in FIG. 17, optionally, the display panel according to the embodiment of the present disclosure includes a base substrate 00 and multiple signal traces 30. The light-emitting element 13 includes an anode layer 131, a light-emitting layer 132, and a cathode layer 133, which are sequentially stacked and arranged on a side of the base substrate 00. The anode layer 131 of the light-emitting element 13 in the first sub-pixel 111 is a first anode layer 131A, and the anode layer 131 of the light-emitting element 13 in the second sub-pixel 112 is a second anode layer 131B. In the thickness direction of the display panel, a distance between the first anode layer 131A and the signal trace 30 overlapped with the first anode layer 131A is greater than a distance between the second anode layer 131B and a signal trace 30 overlapped with the second anode layer 131B.

Specifically, as shown in FIG. 17, in the thickness direction of the display panel, the distance between the first anode layer 131A of the light-emitting element 13 in the first sub-pixel 111 emitting the green light and the signal trace 30 is set to be greater than the distance between the second anode layer 131B of the light-emitting element 13 in the second sub-pixel 112 emitting the red light and/or the blue light and the signal trace 30, so that the parasitic capacitance formed between the first anode layer 131A of the light-emitting element 13 in the first sub-pixel 111 and the signal trace 30 is relatively small, whereas the parasitic capacitance formed between the second anode layer 131B of the light-emitting element 13 in the second sub-pixel 112 and the signal trace 30 is relatively large, that is, a smaller parasitic capacitance is formed at the N4 node in the first sub-pixel 111, and a larger parasitic capacitance is formed at the N4 node in the second sub-pixel 112, whereby when the black picture is switched to the white picture, and the parasitic capacitance at the N4 node in the first sub-pixel 111 is charged for a shorter period of time within the first frame of the white picture, the parasitic capacitance at the N4 node in the second sub-pixel 112 is charged for a longer period of time within the first frame of the white picture, and further, the light-emitting element 13 in the first sub-pixel 111 emits light for a longer duration and the light-emitting element 13 in the second sub-pixel 112 emits light for a shorter duration within the first frame of the white picture, thereby increasing the brightness output by the first sub-pixel 111 in the first frame of the white picture, reducing the brightness output by the second sub-pixel 112 in the first frame of the white picture, so as to compensate for the green light brightness in the first frame of the white picture, improve the phenomenon of the image redness in the first frame of the white picture, and further improve the problem of the color redness caused by a dragging shadow to enable the dragging shadow color observed by the user to be corrected, reduce the severity of the dragging shadow in the visual effect, and thus improve the display effect of the display panel.

With continued reference to FIG. 17, optionally, the number of insulating layers between the first anode layer 131A in the first sub-pixel 111 and the signal trace 30 is set to be greater than the number of insulating layers between the second anode layer 131B in the second sub-pixel 112 and the signal trace 30, so that the distance between the first anode layer 131A in the first sub-pixel 111 and the signal trace 30 is greater than the distance between the second anode layer 131B in the second sub-pixel 112 and the signal trace 30.

The insulating layer may include a gate insulating layer 41 between the active layer 01 and the gate layer 02, an interlayer insulating layer 42 between the gate layer 02 and the source and drain electrode layer 03, and a planarization layer 43 between the source and drain electrode layer 03 and the anode layer 131, but not limited thereto.

FIG. 18 is a schematic view showing a partial cross-sectional structure of still another display panel according to an embodiment of the present disclosure. As shown in FIG. 18, a thickness of the insulating layer between the first anode layer 131A in the first sub-pixel 111 and the signal trace 30 may be set to be greater than a thickness of the insulating layer between the second anode layer 131B in the second sub-pixel 112 and the signal trace 30, so that the distance between the first anode layer 131A in the first sub-pixel 111 and the signal trace 30 is greater than the distance between the second anode layer 131B in the second sub-pixel 112 and the signal trace 30, but not limited thereto, and it may be set by those skilled in the art according to actual requirements.

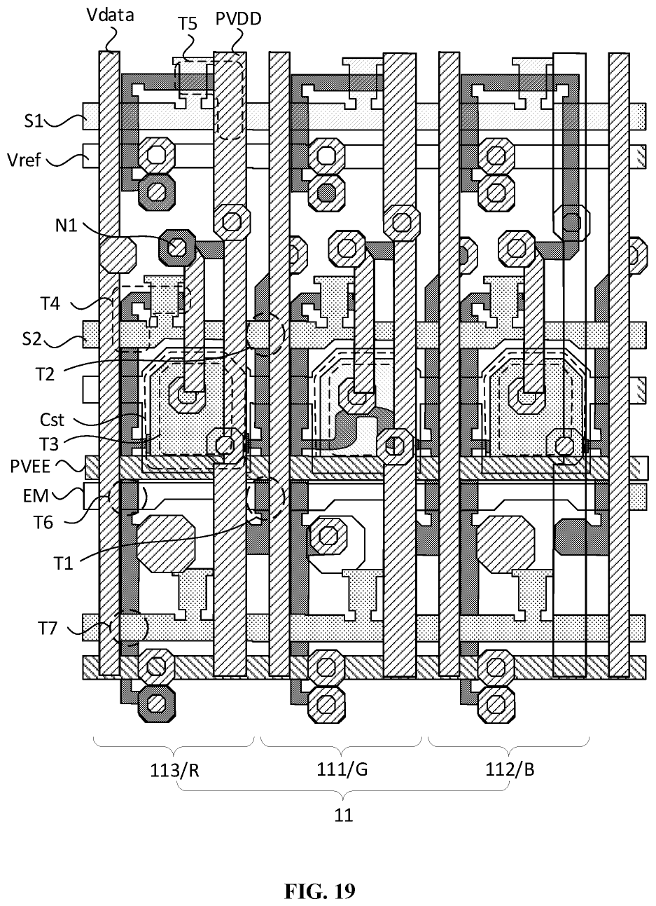

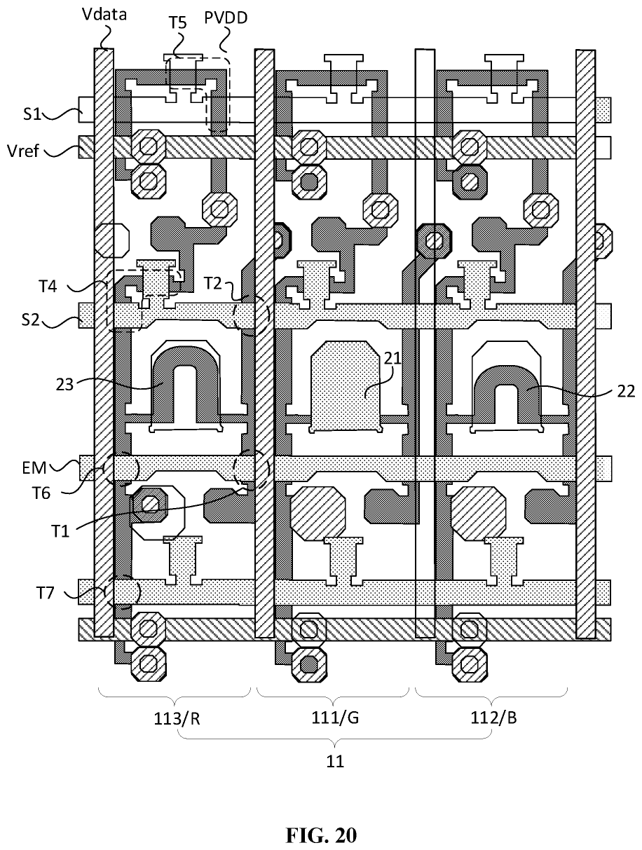

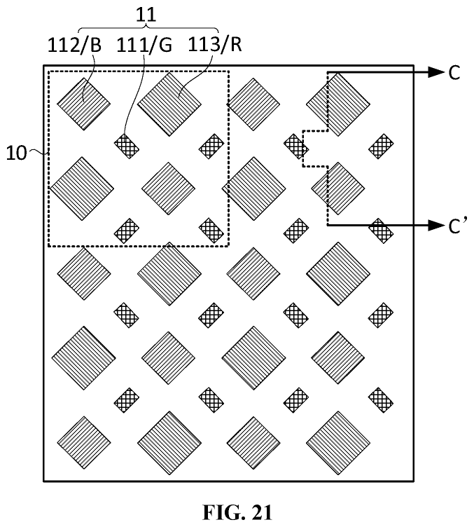

FIG. 19 is a schematic structural view of another pixel circuit according to an embodiment of the present disclosure, and FIG. 20 is a schematic view showing a partial structure of the pixel circuit of FIG. 19. As shown in FIGS. 19 and 20, optionally, the at least two sub-pixels 11 further include a third sub-pixel 113, the second sub-pixel 112 is configured to emit blue light, and the third sub-pixel 113 is configured to emit red light. The drive transistor T3 of the pixel circuit 12 in the third sub-pixel 113 includes a third channel 23, and the width-to-length ratio of the third channel 23 is less than the width-to-length ratio of the second channel 22.

FIG. 19 shows a pixel circuit in one pixel cell. In FIG. 20, part of structures is hidden on the basis of FIG. 19 in order to clearly illustrate the improved structure of the present application.

At the first frame that the black picture is switched to the white picture, the red sub-pixels are brighter, the green sub-pixels are darker, and the brightness of the blue sub-pixels is centered, so that the picture at the first frame that the black picture is switched to the white picture is more reddish, the user observes the reddish lagging shadow when viewing, and the reddish lagging shadow will make the human eye feel the heavier lagging shadow degree in the visual effect, thereby affecting the display effect of the display panel.

In this embodiment, as shown in FIGS. 19 and 20, in the pixel cell, the first sub-pixel 111 is configured to emit green light, the second sub-pixel 112 is configured to emit blue light, and the third sub-pixel 113 is configured to emit red light. The drive transistor T3 in the first sub-pixel 111 has the first channel 21, the drive transistor T3 in the second sub-pixel 112 has the second channel 22, and the drive transistor T3 in the third sub-pixel 113 has the third channel 23.

The width-to-length ratio of the first channel 21 is set to be greater than the width-to-length ratio of the second channel 22, and the width-to-length ratio of the second channel 22 is greater than width-to-length ratio of the third channel 23, so that when the black picture is switched to the white picture, the threshold voltage Vth of the drive transistor T3 in the first sub-pixel 111 is more easily to reach the threshold voltage Vth corresponding to the gate voltage of the white picture, whereas the threshold voltage Vth of the drive transistor T3 in the third sub-pixel 113 is more difficult to reach to the threshold voltage Vth corresponding to the gate voltage of the white picture, whereby the brightness of the first sub-pixel 111 is increased in the first frame of the white picture, the brightness of the third sub-pixel 113 is reduced in the first frame of the white picture, so as to compensate for the green light brightness and reduce the red light brightness in the first frame of the white picture, further reduce the imbalance of the white dot color coordinates caused by the brightness difference of the first frame of the white picture, solve the problem of the color shift of the first frame of the white picture, and further improve the problem of the color redness caused by a dragging shadow to enable the dragging shadow color observed by the user to be corrected, reduce the severity of the dragging shadow in the visual effect, and thus improve the display effect of the display panel.

It should be noted that the adjustment of the width-to-length ratios of the first channel 21, the second channel 22 and the third channel 23 may be referred to the scheme described in any of the above embodiments.

For example, as shown in FIG. 20, the width of the first channel 21, the width of the second channel 22, and the width of the third channel 23 are set to be the same, the length of the first channel 21 is set to be less than the length of the second channel 22, and the length of the second channel 22 is set to be less than the length of the third channel 23, whereby the width-to-length ratio of the first channel 21 is enabled to be greater than the width-to-length ratio of the second channel 22, and the width-to-length ratio of the second channel 22 is enabled to be greater than the width-to-length ratio of the third channel 23 by adjusting the channel lengths of the drive transistors T3 in the first sub-pixel 111, the second sub-pixel 112, and the third sub-pixel 113.

For another example, the length of the first channel 21, the length of the second channel 22, and the length of the third channel 23 are set to be the same, the width of the first channel 21 is set to be greater than the width of the second channel 22, and the width of the second channel 22 is set to be greater than the width of the third channel 23, whereby the width-to-length ratio of the first channel 21 is enabled to be greater than the width-to-length ratio of the second channel 22, and the width-to-length ratio of the second channel 22 is enabled to be greater than the width-to-length ratio of the third channel 23 by adjusting the channel widths of the drive transistors T3 in the first sub-pixel 111, the second sub-pixel 112, and the third sub-pixel 113.

For another example, the length of the first channel 21 is set to be less than the length of the second channel 22, and the length of the second channel 22 is set to be less than the length of the third channel 23; the width of the first channel 21 is set to be greater than the width of the second channel 22, and the width of the second channel 22 is set to be greater than the width of the third channel 23, so that the width-to-length ratio of the first channel 21 is enabled to be greater than the width-to-length ratio of the second channel 22, and the width-to-length ratio of the second channel 22 is enabled to be greater than the width-to-length ratio of the third channel 23, and the details are not repeated here.

Furthermore, the shape arrangement of the first channel 21, the second channel 22 and the third channel 23 may also be referred to the scheme described in any of the above embodiments.

For example, the shapes of the first channel 21, the second channel 22 and the third channel 23 may be set to be U-shape, so that a longer channel may be provided in a limited space, whereby more adjustment space may be provided for width-to-length ratio of the channel to satisfy the correction requirement of the dragging shadow color, and the details are not repeated here.

It should be noted that a specific value of the width-to-length ratio of the first channel 21, a specific value of the width-to-length ratio of the second channel 22, and a specific value of the width-to-length ratio of the third channel 23 are not specifically limited in the embodiments of the present disclosure, and it is only necessary to satisfy that the width-to-length ratio of the first channel 21 is greater than the width-to-length ratio of the second channel 22, and the width-to-length ratio of the second channel 22 is greater than the width-to-length ratio of the third channel 23. For example, the width-to-length ratio of the first channel 21 is 3/16, the width-to-length ratio of the second channel 22 is 3/21, and the width-to-length ratio of the third channel 23 is 3/25, so as to further reduce the imbalance of the white dot color coordinates caused by the brightness difference of the first frame of the white picture, solve the problem of the color shift of the first frame of the white picture, but not limited thereto, and it may be set by those skilled in the art according to actual requirements.

Optionally, the capacitance of the light-emitting element 13 in the first sub-pixel 111 is less than the capacitance of the light-emitting element 13 in the second sub-pixel 112, and the capacitance of the light-emitting element 13 in the second sub-pixel 112 is less than the capacitance of the light-emitting element 13 in the third sub-pixel 113.

In this embodiment, the capacitance of the light-emitting element 13 in the first sub-pixel 111 is set to be less than the capacitance of the light-emitting element 13 in the second sub-pixel 112, and the capacitance of the light-emitting element 13 in the second sub-pixel 112 is set to be less than the capacitance of the light-emitting element 13 in the third sub-pixel 113, so that when the black picture is switched to the white picture, the light-emitting element 13 in the third sub-pixel 113 is charged for a longer period of time within the first frame of the white picture, and the light-emitting element 13 in the first sub-pixel 111 is charged for a shorter period of time within the first frame of the white picture, whereby the light-emitting element 13 in the first sub-pixel 111 emits light for a longer duration and the light-emitting element 13 in the third sub-pixel 113 emits light for a shorter duration within the first frame of the white picture, thereby increasing the brightness output by the first sub-pixel 111 in the first frame of the white picture, reducing the brightness output by the third sub-pixel 113 in the first frame of the white picture, so as to compensate for the green light brightness and reduce the red light brightness in the first frame of the white picture, further reduce the imbalance of the white dot color coordinates caused by the brightness difference of the first frame of the white picture, solve the problem of the color shift of the first frame of the white picture, and further improve the problem of the color redness caused by a dragging shadow to enable the dragging shadow color observed by the user to be corrected, reduce the severity of the dragging shadow in the visual effect, and thus improve the display effect of the display panel.

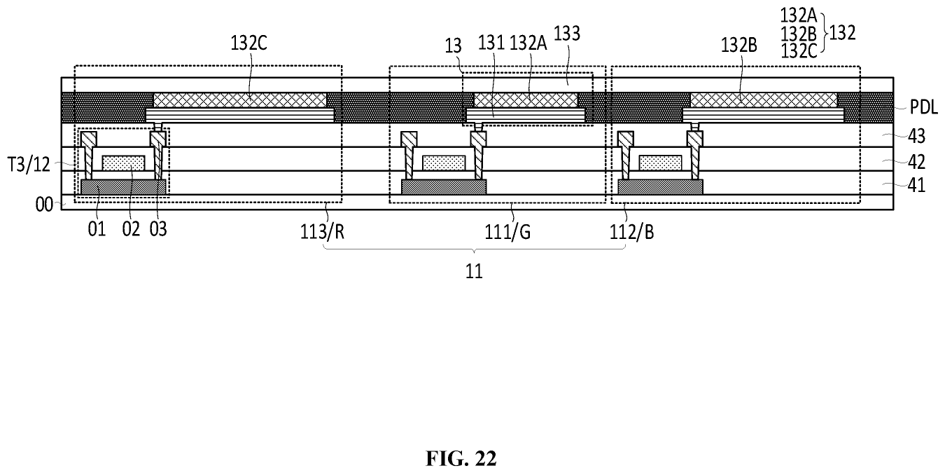

FIG. 21 is a schematic structural view of still another display panel according to an embodiment of the present disclosure, and FIG. 22 is schematic structural cross-sectional view of FIG. 21 taken along a direction of C-C′. As shown in FIGS. 21 and 22, optionally, the display panel according to the embodiment of the present disclosure includes a base substrate 00. The light-emitting element 13 includes an anode layer 131, a light-emitting layer 132 and a cathode layer 133, which are sequentially stacked and arranged on a side of the base substrate 00. The light-emitting layer 132 of the light-emitting element 13 in the first sub-pixel 111 is a first light-emitting layer 132A, the light-emitting layer 132 of the light-emitting element 13 in the second sub-pixel 112 is a second light-emitting layer 132B, the light-emitting layer 132 of the light-emitting element 13 in the third sub-pixel 113 is a third light-emitting layer 132C, an area of the first light-emitting layer 132A is less than an area of the second light-emitting layer 132B, and the area of the second light-emitting layer 132B is less than an area of the third light-emitting layer 132C.

Specifically, as shown in FIGS. 21 and 22, the area of the first light-emitting layer 132A of the light-emitting element 13 in the first sub-pixel 111 emitting the green light is set to be less than the area of the second light-emitting layer 132B of the light-emitting element 13 in the second sub-pixel 112 emitting the blue light, the area of the second light-emitting layer 132B of the light-emitting element 13 in the second sub-pixel 112 emitting the blue light is set to be less than the area of the third light-emitting layer 132C of the light-emitting element 13 in the third sub-pixel 113 emitting the red light, so that the capacitance of the light-emitting element 13 in the first sub-pixel 111 is less than the capacitance of the light-emitting element 13 in the second sub-pixel 112, the capacitance of the light-emitting element 13 in the second sub-pixel 112 is less than the capacitance of the light-emitting element 13 in the third sub-pixel 113, and further so that when the black picture is switched to the white picture, the light-emitting element 13 in the first sub-pixel 111 is charged for a shorter period of time within the first frame of the white picture, and the light-emitting element 13 in the third sub-pixel 113 is charged for a longer period of time within the first frame of the white picture, whereby the light-emitting element 13 in the first sub-pixel 111 emits light for a longer duration and the light-emitting element 13 in the third sub-pixel 113 emits light for a shorter duration within the first frame of the white picture, thereby increasing the brightness output by the first sub-pixel 111 in the first frame of the white picture, reducing the brightness output by the third sub-pixel 113 in the first frame of the white picture, so as to compensate for the green light brightness and reduce the red light brightness in the first frame of the white picture, further reduce the imbalance of the white dot color coordinates caused by the brightness difference of the first frame of the white picture, solve the problem of the color shift of the first frame of the white picture, and further improve the problem of the color redness caused by a dragging shadow to enable the dragging shadow color observed by the user to be corrected, reduce the severity of the dragging shadow in the visual effect, and thus improve the display effect of the display panel.

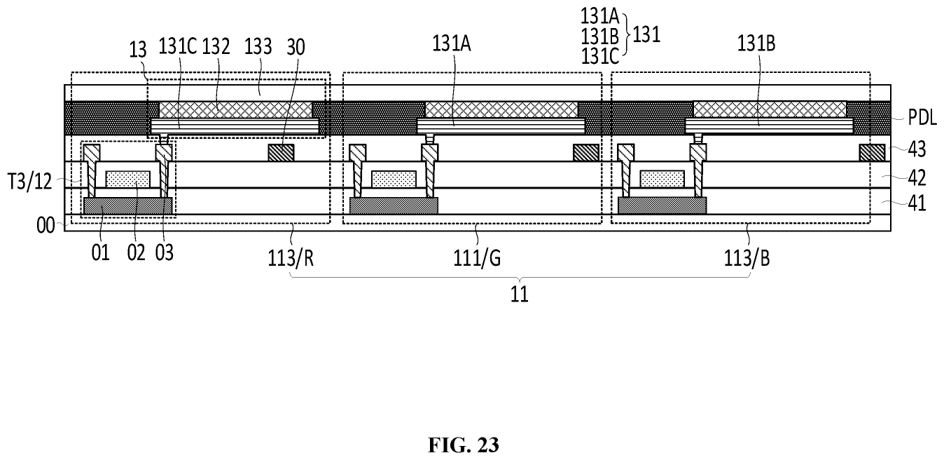

FIG. 23 is a schematic view showing a partial cross-sectional structure of still another display panel according to an embodiment of the present disclosure. As shown in FIG. 23, optionally, the display panel according to the embodiment of the present disclosure includes a base substrate 00 and multiple signal traces 30. The light-emitting element 13 includes an anode layer 131, a light-emitting layer 132 and a cathode layer 133, which are sequentially stacked and arranged on a side of the base substrate 00. The anode layer 131 of the light-emitting element 13 in the first sub-pixel 111 is a first anode layer 131A, the anode layer 131 of the light-emitting element 13 in the second sub-pixel 112 is a second anode layer 131B, and the anode layer 131 of the light-emitting element 13 in the third sub-pixel 113 is a third anode layer 131C. In a thickness direction of the display panel, an overlapping area of the first anode layer 131A and a signal trace 30 is less than an overlapping area of the second anode layer 131B and a signal trace 30, and the overlapping area of the second anode layer 131B and the signal trace 30 is less than an overlapping area of the third anode layer 131C and a signal trace 30.

Specifically, as shown in FIG. 23, in the thickness direction of the display panel, the overlapping area between the first anode layer 131A of the light-emitting element 13 in the first sub-pixel 111 emitting the green light and the signal trace 30 is set to be less than the overlapping area between the second anode layer 131B of the light-emitting element 13 in the second sub-pixel 112 emitting the blue light and the signal trace 30, the overlapping area between the second anode layer 131B of the light-emitting element 13 in the second sub-pixel 112 emitting the blue light and the signal trace 30 is less than the overlapping area between the third anode layer 131C of the light-emitting element 13 in the third sub-pixel 113 emitting the red light and the signal trace 30, so that the parasitic capacitance formed between the first anode layer 131A of the light-emitting element 13 in the first sub-pixel 111 and the signal trace 30 is relatively small, whereas the parasitic capacitance formed between the third anode layer 131C of the light-emitting element 13 in the third sub-pixel 113 and the signal trace 30 is relatively large, that is, a smaller parasitic capacitance is formed at the N4 node in the first sub-pixel 111, and a larger parasitic capacitance is formed at the N4 node in the third sub-pixel 113, whereby when the black picture is switched to the white picture, and the parasitic capacitance at the N4 node in the first sub-pixel 111 is charged for a shorter period of time within the first frame of the white picture, the parasitic capacitance at the N4 node in the third sub-pixel 113 is charged for a longer period of time within the first frame of the white picture, and further, the light-emitting element 13 in the first sub-pixel 111 emits light for a longer duration and the light-emitting element 13 in the third sub-pixel 113 emits light for a shorter duration within the first frame of the white picture, thereby increasing the brightness output by the first sub-pixel 111 in the first frame of the white picture, reducing the brightness output by the third sub-pixel 113 in the first frame of the white picture, so as to compensate for the green light brightness and reduce the red light brightness in the first frame of the white picture, further reduce the imbalance of the white dot color coordinates caused by the brightness difference of the first frame of the white picture, solve the problem of the color shift of the first frame of the white picture, and further improve the problem of the color redness caused by a dragging shadow to enable the dragging shadow color observed by the user to be corrected, reduce the severity of the dragging shadow in the visual effect, and thus improve the display effect of the display panel.

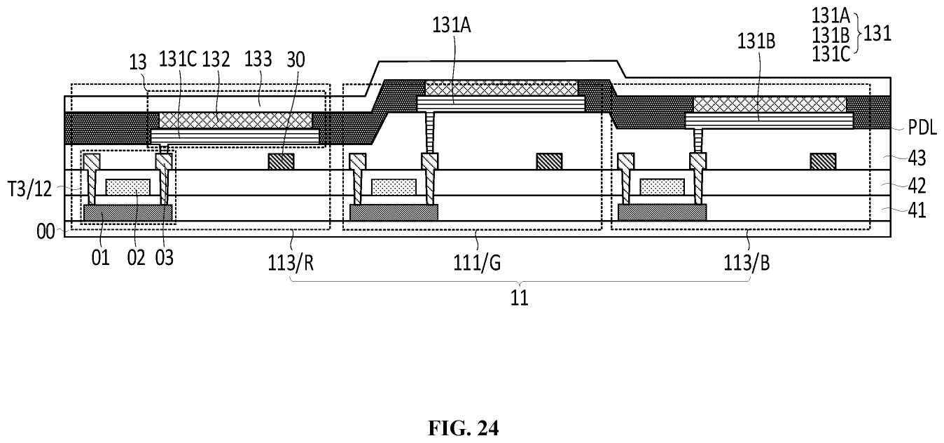

FIG. 24 is a schematic view showing a partial cross-sectional structure of still another display panel according to an embodiment of the present disclosure. As shown in FIG. 24, optionally, the display panel according to the embodiment of the present disclosure includes a base substrate 00 and multiple signal traces 30. The light-emitting element 13 includes an anode layer 131, a light-emitting layer 132 and a cathode layer 133, which are sequentially stacked and arranged on a side of the base substrate 00. The anode layer 131 of the light-emitting element 13 in the first sub-pixel 111 is a first anode layer 131A, the anode layer 131 of the light-emitting element 13 in the second sub-pixel 112 is a second anode layer 131B, and the anode layer 131 of the light-emitting element 13 in the third sub-pixel 113 is a third anode layer 131C. In a thickness direction of the display panel, a distance between the first anode layer 131A and a signal trace 30 overlapped with the first anode layer 131A is greater than a distance between the second anode layer 131B and a signal trace 30 overlapped with the second anode layer 131B, and a distance between the second anode layer 131B and the signal trace 30 overlapped with the second anode layer 131B is greater than a distance between the third anode layer 131C and a signal trace 30 overlapped with the third anode layer 131C.

Specifically, as shown in FIG. 24, in the thickness direction of the display panel, the distance between the first anode layer 131A of the light-emitting element 13 in the first sub-pixel 111 emitting the green light and the signal trace 30 is set to be greater than the distance between the second anode layer 131B of the light-emitting element 13 in the second sub-pixel 112 emitting the blue light and the signal trace 30, the distance between the second anode layer 131B of the light-emitting element 13 in the second sub-pixel 112 emitting the blue light and the signal trace 30 is set to be greater than the distance between the third anode layer 131C of the light-emitting element 13 in the third sub-pixel 113 emitting the red light and the signal trace 30, so that the parasitic capacitance formed between the first anode layer 131A of the light-emitting element 13 in the first sub-pixel 111 and the signal trace 30 is relatively small, whereas the parasitic capacitance formed between the third anode layer 131C of the light-emitting element 13 in the third sub-pixel 113 and the signal trace 30 is relatively large, that is, a smaller parasitic capacitance is formed at the N4 node in the first sub-pixel 111, and a larger parasitic capacitance is formed at the N4 node in the third sub-pixel 113, whereby when the black picture is switched to the white picture, and the parasitic capacitance at the N4 node in the first sub-pixel 111 is charged for a shorter period of time within the first frame of the white picture, the parasitic capacitance at the N4 node in the third sub-pixel 113 is charged for a longer period of time within the first frame of the white picture, and further, the light-emitting element 13 in the first sub-pixel 111 emits light for a longer duration and the light-emitting element 13 in the third sub-pixel 113 emits light for a shorter duration within the first frame of the white picture, thereby increasing the brightness output by the first sub-pixel 111 in the first frame of the white picture, reducing the brightness output by the third sub-pixel 113 in the first frame of the white picture, so as to compensate for the green light brightness and reduce the red light brightness in the first frame of the white picture, further reduce the imbalance of the white dot color coordinates caused by the brightness difference of the first frame of the white picture, solve the problem of the color shift of the first frame of the white picture, and further improve the problem of the color redness caused by a dragging shadow to enable the dragging shadow color observed by the user to be corrected, reduce the severity of the dragging shadow in the visual effect, and thus improve the display effect of the display panel.

With continued reference to FIG. 24, a thickness of the insulating layer between the first anode layer 131A in the first sub-pixel 111 and the signal trace 30 may be set to be greater than a thickness of the insulating layer between the second anode layer 131B in the second sub-pixel 112 and the signal trace 30, the thickness of the insulating layer between the second anode layer 131B in the second sub-pixel 112 and the signal trace 30 may be set to be greater than a thickness of the insulating layer between the third anode layer 131C in the third sub-pixel 113 and the signal trace 30, so that the distance between the first anode layer 131A in the first sub-pixel 111 and the signal trace 30 is greater than the distance between the second anode layer 131B in the second sub-pixel 112 and the signal trace 30, and the distance between the second anode layer 131B in the second sub-pixel 112 and the signal trace 30 is greater than the distance between the third anode layer 131C in the third sub-pixel 113 and the signal trace 30, but not limited thereto.

In some embodiments, the number of insulating layers between the first anode layer 131A in the first sub-pixel 111 and the signal trace 30 may also be set to be greater than the number of insulating layers between the second anode layer 131B in the second sub-pixel 112 and the signal trace 30, and the number of insulating layers between the second anode layer 131B in the second sub-pixel 112 and the signal trace 30 is greater than the number of insulating layers between the third anode layer 131C in the third sub-pixel 113 and the signal trace 30, so that the distance between the first anode layer 131A in the first sub-pixel 111 and the signal trace 30 is greater than the distance between the second anode layer 131B in the second sub-pixel 112 and the signal trace 30, and the distance between the second anode layer 131B in the second sub-pixel 112 and the signal trace 30 is greater than the distance between the third anode layer 131C in the third sub-pixel 113 and the signal trace 30, and it may be set by those skilled in the art according to actual requirements.

With continued reference to FIGS. 3 and 6, optionally, the display panel according to the embodiment of the present disclosure includes a first power supply signal line PVDD, a second power supply signal line PVEE, a first scan signal line S1, a reference signal line Vref, a second scan signal line S2, a data signal line Vdata, and a light-emitting control signal line EM. The pixel circuit 12 further includes a first reset transistor T5, a light-emitting reset transistor T7, a data write transistor T2, an additional transistor T4 and a light-emitting control transistor T1/T6. The first power supply signal line PVDD is configured to transmit a first power supply voltage, the second power supply signal line PVEE is configured to transmit a second power supply voltage, and the first power supply voltage is greater than the second power supply voltage. The drive transistor T3, the light-emitting control transistor T1/T6 and the light-emitting element 13 are connected in series between the first power supply signal line PVDD and the second power supply signal line PVEE. A gate of the first reset transistor T5 is electrically connected to the first scan signal line S1, a first electrode of the first reset transistor T5 is electrically connected to the reference signal line Vref, and a second electrode of the first reset transistor T5 is electrically connected to a gate of the drive transistor T3. A gate of the light-emitting reset transistor T7 is electrically connected to the second scan signal line S2, the first electrode of the light-emitting reset transistor T7 is electrically connected to the reference signal line Vref, and a second electrode of the light-emitting reset transistor T7 is electrically connected to the light-emitting element 13. A gate of the data write transistor T2 is electrically connected to the second scan signal line S2, a first electrode of the data write transistor T2 is electrically connected to the data signal line Vdata, and a second electrode of the data write transistor T2 is electrically connected to a first electrode of the drive transistor T3. A gate of the additional transistor T4 is electrically connected to the second scan signal line S2, a first electrode of the additional transistor T4 is electrically connected to a second electrode of the drive transistor T3, and a second electrode of the additional transistor T4 is electrically connected to the gate of the drive transistor T3. A gate of the light-emitting control transistor T1/T6 is electrically connected to the light-emitting control signal line EM. The signal traces 30 includes at least one of the first power supply signal line PVDD, the second power supply signal line PVEE, the first scan signal line S1, the second scan signal line S2, the reference signal line Vref, the data signal line Vdata, or the light-emitting control signal line EM.

Further, the pixel circuit 12 further includes a capacitance Cst, one plate of the capacitance Cst is electrically connected to the first power supply signal line PVDD, and another plate of the capacitance Cst is electrically connected to the gate of the drive transistor T3.

Specifically, as shown in FIGS. 3 and 6, a driving process of the pixel circuit 12 is, for example, as follows.

In an initialization phase, a first scan signal on the first scan signal line S1 causes the first reset transistor T5 to be turned on, and a reference voltage on the reference signal line Vref is applied to one end of the capacitance Cst through the first reset transistor T5, that is, a potential of a first node N1 is the reference voltage to reset the first node N1, and at this time, a gate potential of the drive transistor T3 is also the reference voltage.

In a data signal voltage write phase, a second scan signal on the second scan signal line S2 causes the data write transistor T2 and the additional transistor T4 to be turned on. At this time, a potential of the gate of the drive transistor T3 is the reference voltage, the drive transistor T3 is also turned on, and a data signal voltage on the data signal line Vdata is applied to the first node N1 through the data write transistor T2, the drive transistor T3 and the additional transistor T4, thereby writing the data signal voltage into the capacitance Cst.

Meanwhile, in the data signal voltage write phase, the second scan signal on the second scan signal line S2 causes the light-emitting reset transistor T7 to be turned on, and the light-emitting reset transistor T7 writes the reference voltage on the reference signal line Vref to an anode of the light-emitting element 13, and resets a potential of the anode of the light-emitting element 13, so that the influence of a voltage of an anode of a previous frame of light-emitting element 13 on a voltage of an anode of a subsequent frame of light-emitting element 13 can be reduced, thereby further improving the display uniformity.

In a light-emitting stage, a light-emitting control signal on the light-emitting control signal line EM causes the light-emitting control transistor T1/T6 to be turned on, so that the light-emitting element 13 is driven to emit light through the drive transistor T3, and thus, the light-emitting and display functions of the display panel are achieved.

In this embodiment, at least one of the first power supply signal line PVDD, the second power supply signal line PVEE, the first scan signal line S1, the second scan signal line S2, the reference signal line Vref, the data signal line Vdata, or the light-emitting control signal line EM may be used as the signal trace 30 described in the above-described embodiments, so that a magnitude of the parasitic capacitance formed at the N4 node is adjusted, a small parasitic capacitance is formed at the N4 node in the first sub-pixel 111, and a large parasitic capacitance is formed at the N4 node in the second sub-pixel 112, whereby when the black picture is switched to the white picture, and the parasitic capacitance at the N4 node in the first sub-pixel 111 is charged for a shorter period of time within the first frame of the white picture, the parasitic capacitance at the N4 node in the second sub-pixel 112 is charged for a longer period of time within the first frame of the white picture, and further, the light-emitting element 13 in the first sub-pixel 111 emits light for a longer duration and the light-emitting element 13 in the second sub-pixel 112 emits light for a shorter duration within the first frame of the white picture, thereby increasing the brightness output by the first sub-pixel 111 in the first frame of the white picture, reducing the brightness output by the second sub-pixel 112 in the first frame of the white picture, so as to compensate for the green light brightness in the first frame of the white picture, improve the phenomenon of the image redness in the first frame of the white picture, and further improve the problem of the color redness caused by a dragging shadow to enable the dragging shadow color observed by the user to be corrected, reduce the severity of the dragging shadow in the visual effect, and thus improve the display effect of the display panel.

It is to be understood that in the above-described embodiments, only a structure of the pixel circuit 12 is illustrated by way of example. However, in a specific implementation, the pixel circuit 12 is not limited to the structure in the above-described embodiments, details are not described herein in this embodiment, and will be understood with reference to the structure of the pixel circuit in the related art.

It should be noted that in the above-described implementation, each transistor may be a P-type transistor or a N-type transistor. Alternatively, a part of transistors are P-type transistors, and a part of the transistors are N-type transistors, which is not limited in the embodiments of the present disclosure.

Optionally, the first reset transistor T5 may be provided as an oxide semiconductor transistor, such as an N-type indium gallium zinc oxide (IGZO) transistor. When the first scan signal on the first scan signal line S1 is a high-level signal, a source and drain of the N-type oxide semiconductor transistor is turned on so that the first reset transistor T5 is turned on. Since the IGZO transistor has low mobility and small leakage current, the first reset transistor T5 employs the oxide semiconductor transistor, so that a charge on the gate of the drive transistor T3 can be prevented from being leaked out through the first reset transistor T5 during a low-frequency driving, and a problem of the leakage current during the low-frequency driving can be effectively solved, whereby the pixel circuit 12 is suitable for achieving the low-frequency driving, which is conductive to reducing the power consumption of the display panel.

Optionally, the additional transistor T4 may also be an oxide semiconductor transistor, such as an N-type indium gallium zinc oxide (IGZO) transistor. When the second scan signal on the second scan signal line S2 is a high-level signal, the source and drain of the N-type oxide semiconductor transistor is turned on so that the additional transistor T4 is turned on. Since the IGZO transistor has low mobility and small leakage current, the additional transistor T4 employs the oxide semiconductor transistor, so that a charge on the gate of the drive transistor T3 can be prevented from being leaked out through the additional transistor T4 during the low-frequency driving, the influence of the leakage current on the stability of the potential of the gate of the drive transistor T3 can be effectively reduced, which is conductive to improving the stability of the pixel circuit 12 during the low-frequency driving.

Optionally, the light-emitting control transistor T1/T6, the data write transistor T2, the drive transistor T3 and the light-emitting reset transistor T7 may be a P-type low temperature poly-silicon (LTPS) thin film transistor (P-type transistor), and the LTPS transistor has the advantages of small size and good stability.

With continued reference to FIGS. 3 and 6, optionally, the additional transistor T4 and the first reset transistor T5 are dual-gate transistors.

A leakage current of the dual-gate transistor is small, and the additional transistor T4 and the first reset transistor T5 adopt the dual-gate transistor, so that a charge on the gate of the drive transistor T3 can be prevented from being leaked out through the additional transistor T4 and the first reset transistor T5 during the low-frequency driving, and a problem of the leakage current during the low-frequency driving can be effectively solved, whereby the pixel circuit 12 is suitable for achieving the low-frequency driving, which is conductive to reducing the power consumption of the display panel.

Meanwhile, when the additional transistor T4 and the first reset transistor T5 are oxide semiconductor transistors, since the size of the oxide semiconductor transistor is generally relatively large, the oxide semiconductor transistor being set as the dual-gate transistor helps to reduce the sizes of the additional transistor T4 and the first reset transistor T5.

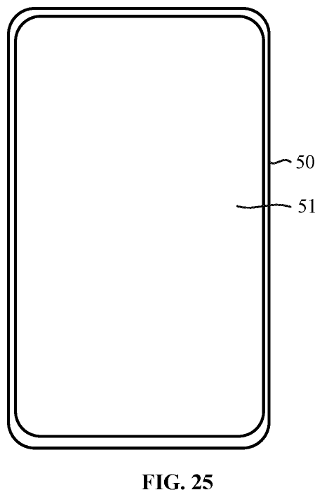

The embodiment of the present disclosure further provides a display device. FIG. 25 is a schematic structural view of a display device according to an embodiment of the present disclosure. As shown in FIG. 25, the display device 50 includes the display panel 51 described in any of the embodiments of the present disclosure. Therefore, the display device 50 provided in the embodiments of the present disclosure has the effects of the schemes in any one of the above-described embodiments, and the explanation of the structure and terminology identical to or corresponding to the above-described embodiments is not described herein in detail.

The display device 50 provided in the embodiments of the present disclosure may be the mobile phone shown in FIG. 25, or may be any electronic product having the display function, and the any electronic product having the display function includes, but not limited to, the following categories: a television, a notebook computer, a desktop display, a tablet computer, a digital camera, a smart wrist strap, smart glasses, an in-vehicle display, a medical apparatus, an industrial control apparatus, a touch interaction terminal, and the like, which is not particularly limited in the embodiments of the present disclosure.

The above implementations should not be construed as limiting the scope of protection of the present disclosure. It should be understood by those skilled in the art that various modifications, combinations, sub-combinations and substitutions may be made depending on design requirements and other factors. Any modification, equivalent replacement, and improvement made within the spirit and principle of the present disclosure should be included within the scope of protection of the present disclosure.

What is claimed is:

1. A display panel, comprising a plurality of pixel cells, each of the plurality of pixel cells comprises at least two sub-pixels, each of the at least two sub-pixels comprises a pixel circuit and a light-emitting element, the pixel circuit is configured to drive the light-emitting element to emit light, and the pixel circuit comprises a drive transistor;
the at least two sub-pixels comprise a first sub-pixel and a second sub-pixel, the first sub-pixel is configured to emit green light, and the second sub-pixel is configured to emit at least one of red light or blue light;
the drive transistor of the pixel circuit in the first sub-pixel comprises a first channel, and the drive transistor of the pixel circuit in the second sub-pixel comprises a second channel; and
a width-to-length ratio of the first channel is greater than a width-to-length ratio of the second channel.

2. The display panel of claim 1, wherein a width of the first channel is the same as a width of the second channel, and a length of the first channel is less than a length of the second channel.

3. The display panel of claim 1, wherein a length of the first channel is the same as a length of the second channel, and a width of the first channel is greater than a width of the second channel.

4. The display panel of claim 1, wherein a length of the first channel is less than a length of the second channel, and a width of the first channel is greater than a width of the second channel.

5. The display panel of claim 1, wherein a shape of the first channel comprises a U-shape, and a shape of the second channel comprises the U-shape.

6. The display panel of claim 5, wherein,
the first channel comprises a first segment, a second segment connected to one end of the first segment, and a third segment connected to another end of the first segment, an extension direction of the second segment is the same as an extension direction of the third segment, the extension direction of the second segment intersects an extension direction of the first segment, and a length of the second segment is the same as a length of the third segment;
the second channel comprises a fourth segment, a fifth segment connected to one end of the fourth segment, and a sixth segment connected to another end of the fourth segment, an extension direction of the fifth segment is the same as an extension direction of the sixth segment, the extension direction of the fifth segment intersects an extension direction of the fourth segment, and a length of the fifth segment is the same as a length of the sixth segment; and
a length of the first segment is the same as a length of the fourth segment, and the length of the second segment is less than the length of the fifth segment.

7. The display panel of claim 2, wherein the first channel comprises n first fold line segments connected in sequence, and two connected first fold line segments among the n first fold line segments have different extension directions, the second channel comprises m second fold line segments connected in sequence, two connected second fold line segments among the m second fold line segments have different extension directions, wherein 0<n<m, and n and m are both positive integers.

8. The display panel of claim 7, wherein,
a shape of the first channel comprises a U-shape;
a shape of the second channel comprises a dual U-shape, the dual U-shape comprises a first U-shaped portion and a second U-shaped portion, the first U-shaped portion and the second U-shaped portion share a same edge, and an opening direction of the first U-shaped portion is different from an opening direction of the second U-shaped portion.

9. The display panel of claim 2, wherein,
a shape of the first channel comprises a straight line; and
the second channel comprises at least two second fold line segments connected in sequence, and the two connected second fold line segments have different extension directions.

10. The display panel of claim 1, wherein a capacitance of the light-emitting element in the first sub-pixel is less than a capacitance of the light-emitting element in the second sub-pixel.

11. The display panel of claim 10, wherein,
the display panel comprises a base substrate, and the light-emitting element comprises an anode layer, a light-emitting layer and a cathode layer which are sequentially stacked and arranged on a side of the base substrate; and
the light-emitting layer of the light-emitting element in the first sub-pixel is a first light-emitting layer, the light-emitting layer of the light-emitting element in the second sub-pixel is a second light-emitting layer, and an area of the first light-emitting layer is less than an area of the second light-emitting layer.

12. The display panel of claim 1, wherein,
the display panel comprises a base substrate and a plurality of signal traces;
the light-emitting element comprises an anode layer, a light-emitting layer and a cathode layer which are sequentially stacked and arranged on a side of the base substrate;
the anode layer of the light-emitting element in the first sub-pixel is a first anode layer, and the anode layer of the light-emitting element in the second sub-pixel is a second anode layer; and
in a thickness direction of the display panel, an overlapping area of the first anode layer and a signal trace corresponding to the first anode layer among the plurality of signal traces is less than an overlapping area of the second anode layer and a signal trace corresponding to the second anode layer among the plurality of signal traces.

13. The display panel of claim 1, wherein,
the display panel comprises a base substrate and a plurality of signal traces;
the light-emitting element comprises an anode layer, a light-emitting layer and a cathode layer which are sequentially stacked and arranged on a side of the base substrate;
the anode layer of the light-emitting element in the first sub-pixel is a first anode layer, and the anode layer of the light-emitting element in the second sub-pixel is a second anode layer; and
in a thickness direction of the display panel, a distance between the first anode layer and a signal trace overlapped with the first anode layer among the plurality of signal traces is greater than a distance between the second anode layer and a signal trace overlapped with the second anode layer among the plurality of signal traces.

14. The display panel of claim 1, wherein,
the at least two sub-pixels further comprise a third sub-pixel, the second sub-pixel is configured to emit blue light, and the third sub-pixel is configured to emit red light;
the drive transistor of the pixel circuit in the third sub-pixel comprises a third channel; and
a width-to-length ratio of the third channel is less than the width-to-length ratio of the second channel.

15. The display panel of claim 14, wherein a capacitance of the light-emitting element in the first sub-pixel is less than a capacitance of the light-emitting element in the second sub-pixel, and the capacitance of the light-emitting element in the second sub-pixel is less than a capacitance of the light-emitting element in the third sub-pixel.

16. The display panel of claim 15, wherein,
the display panel comprises a base substrate and a plurality of signal traces;
the light-emitting element comprises an anode layer, a light-emitting layer and a cathode layer which are sequentially stacked and arranged on a side of the base substrate;
the anode layer of the light-emitting element in the first sub-pixel is a first anode layer, the anode layer of the light-emitting element in the second sub-pixel is a second anode layer, and the anode layer of the light-emitting element in the third sub-pixel is a third anode layer; and
in a thickness direction of the display panel, an overlapping area of the first anode layer and a signal trace corresponding to the first anode layer among the plurality of signal traces is less than an overlapping area of the second anode layer and a signal trace corresponding to the second anode layer among the plurality of signal traces, and the overlapping area of the second anode layer and the signal trace corresponding to the second anode layer among the plurality of signal traces is less than an overlapping area of the third anode layer and a signal trace corresponding to the third anode layer among the plurality of signal traces.

17. The display panel of claim 14, wherein,
the display panel comprises a base substrate and a plurality of signal traces;
the light-emitting element comprises an anode layer, a light-emitting layer and a cathode layer which are sequentially stacked and arranged on a side of the base substrate;
the anode layer of the light-emitting element in the first sub-pixel is a first anode layer, the anode layer of the light-emitting element in the second sub-pixel is a second anode layer, and the anode layer of the light-emitting element in the third sub-pixel is a third anode layer; and
in a thickness direction of the display panel, a distance between the first anode layer and a signal trace overlapped with the first anode layer among the plurality of signal traces is greater than a distance between the second anode layer and a signal trace overlapped with the second anode layer among the plurality of signal traces, and the distance between the second anode layer and the signal trace overlapped with the second anode layer among the plurality of signal traces is greater than a distance between the third anode layer and a signal trace overlapped with the third anode layer among the plurality of signal traces.

18. The display panel of claim 12, wherein,
the display panel comprises a first power supply signal line, a second power supply signal line, a first scan signal line, a reference signal line, a second scan signal line, a data signal line and a light-emitting control signal line;
the pixel circuit further comprises a first reset transistor, a light-emitting reset transistor, a data write transistor, an additional transistor and a light-emitting control transistor;
the first power supply signal line is configured to transmit a first power supply voltage, the second power supply signal line is configured to transmit a second power supply voltage, and the first power supply voltage is greater than the second power supply voltage;
the drive transistor, the light-emitting control transistor and the light-emitting element are connected in series between the first power supply signal line and the second power supply signal line;
a gate of the first reset transistor is electrically connected to the first scan signal line, a first electrode of the first reset transistor is electrically connected to the reference signal line, and a second electrode of the first reset transistor is electrically connected to a gate of the drive transistor;
a gate of the light-emitting reset transistor is electrically connected to the second scan signal line, a first electrode of the light-emitting reset transistor is electrically connected to the reference signal line, and a second electrode of the light-emitting reset transistor is electrically connected to the light-emitting element;
a gate of the data write transistor is electrically connected to the second scan signal line, a first electrode of the data write transistor is electrically connected to the data signal line, and a second electrode of the data write transistor is electrically connected to a first electrode of the drive transistor;
a gate of the additional transistor is electrically connected to the second scan signal line, a first electrode of the additional transistor is electrically connected to a second electrode of the drive transistor, and a second electrode of the additional transistor is electrically connected to the gate of the drive transistor;
a gate of the light-emitting control transistor is electrically connected to the light-emitting control signal line; and
the plurality of signal traces comprise at least one of the first power supply signal line, the second power supply signal line, the first scan signal line, the second scan signal line, the reference signal line, the data signal line, or the light-emitting control signal line.

19. The display panel of claim 13, wherein,
the display panel comprises a first power supply signal line, a second power supply signal line, a first scan signal line, a reference signal line, a second scan signal line, a data signal line and a light-emitting control signal line;
the pixel circuit further comprises a first reset transistor, a light-emitting reset transistor, a data write transistor, an additional transistor and a light-emitting control transistor;
the first power supply signal line is configured to transmit a first power supply voltage, the second power supply signal line is configured to transmit a second power supply voltage, and the first power supply voltage is greater than the second power supply voltage;
the drive transistor, the light-emitting control transistor and the light-emitting element are connected in series between the first power supply signal line and the second power supply signal line;
a gate of the first reset transistor is electrically connected to the first scan signal line, a first electrode of the first reset transistor is electrically connected to the reference signal line, and a second electrode of the first reset transistor is electrically connected to a gate of the drive transistor;
a gate of the light-emitting reset transistor is electrically connected to the second scan signal line, a first electrode of the light-emitting reset transistor is electrically connected to the reference signal line, and a second electrode of the light-emitting reset transistor is electrically connected to the light-emitting element;
a gate of the data write transistor is electrically connected to the second scan signal line, a first electrode of the data write transistor is electrically connected to the data signal line, and a second electrode of the data write transistor is electrically connected to a first electrode of the drive transistor;
a gate of the additional transistor is electrically connected to the second scan signal line, a first electrode of the additional transistor is electrically connected to a second electrode of the drive transistor, and a second electrode of the additional transistor is electrically connected to the gate of the drive transistor;
a gate of the light-emitting control transistor is electrically connected to the light-emitting control signal line; and
the plurality of signal traces comprise at least one of the first power supply signal line, the second power supply signal line, the first scan signal line, the second scan signal line, the reference signal line, the data signal line, or the light-emitting control signal line.

20. A display device comprising a display panel, wherein the display panel comprises:
a plurality of pixel cells, each of the plurality of pixel cells comprises at least two sub-pixels, each of the at least two sub-pixels comprises a pixel circuit and a light-emitting element, the pixel circuit is configured to drive the light-emitting element to emit light, and the pixel circuit comprises a drive transistor;
the at least two sub-pixels comprise a first sub-pixel and a second sub-pixel, the first sub-pixel is configured to emit green light, and the second sub-pixel is configured to emit at least one of red light or blue light;
the drive transistor of the pixel circuit in the first sub-pixel comprises a first channel, and the drive transistor of the pixel circuit in the second sub-pixel comprises a second channel; and
a width-to-length ratio of the first channel is greater than a width-to-length ratio of the second channel.
